(19) United States
(12) Patent Application Publication
(10) Pub. No.: US 2025/0081743 A1
(43) Pub. Date: Mar. 6, 2025

(54) DISPLAY DEVICE AND METHOD OF MANUFACTURING THE SAME

(71) Applicant: Samsung Display Co., LTD., Yongin-si (KR)

(72) Inventors: Gun Shik KIM, Yongin-si (KR); Woong Sik KIM, Yongin-si (KR); Dae Ho SONG, Yongin-si (KR); Duck Jung LEE, Yongin-si (KR)

(73) Assignee: Samsung Display Co., LTD., Yongin-si (KR)

(21) Appl. No.: 18/655,868

(22) Filed: May 6, 2024

(30) Foreign Application Priority Data
Aug. 30, 2023 (KR) 10-2023-0114400

(51) Int. Cl. H10K 59/122; G02B 27/01; H10K 59/12; H10K 59/131; H10K 59/35; H10K 59/80; H10K 71/20

(52) U.S. Cl. CPC H10K 59/122; H10K 59/1201; H10K 59/131; H10K 59/35; H10K 59/80522; H10K 59/873; H10K 71/233; G02B 2027/0132; G02B 27/0172; G02B 2027/0178

(57) ABSTRACT

A display device may include a pixel defining layer defining subpixels, a pixel electrode of each subpixel disposed in an opening of the pixel defining layer, a trench formed by etching a portion of the pixel defining layer and surrounding a portion of each of the subpixels, heating wires disposed on the pixel defining layer and spaced apart from each other with the trench between the heating wires, a first organic material covering a first pixel electrode of a first subpixel and a portion of the pixel defining layer surrounding the first pixel electrode, a second organic material covering a second pixel electrode of a second subpixel and a portion of the pixel defining layer surrounding the second pixel electrode, and a third organic material covering a third pixel electrode of a third subpixel and a portion of the pixel defining layer surrounding the third pixel electrode.

### CROSS REFERENCE TO RELATED APPLICATION(S)

This application claims to and benefits of Korean Patent Application No. 10-2023-0114400 under 35 U.S.C. § 119, filed on Aug. 30, 2023, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of at least 2000 pixels per inch (PPI) so that a user may use it for a long time without dizziness. Organic light emitting diode on silicon (OLEDoS) technology, which is a small high-resolution organic light emitting display device, is being proposed. The OLEDoS is a technology for placing an organic light emitting diode (OLED) on a semiconductor wafer substrate on which a complementary metal oxide semiconductor (CMOS) is disposed.

Since a distance between pixels is reduced in a display panel to which the OLEDoS technology has been applied, an unintended leakage current may be generated between adjacent pixels. The leakage current may be generated through some conductive layers among intermediate layers disposed between a pixel electrode (e.g., an anode) and a common electrode (e.g., cathode). The leakage current is known to be a cause of color crosstalk between adjacent pixels.

### SUMMARY

Embodiments provide a display device and a method of manufacturing the display device, in which leakage current is prevented by depositing and patterning an organic material for each subpixel using a heating wire, and the encapsulation performance of the organic material may be improved using a trench.

According to an embodiment, a method of manufacturing a display device may include forming a semiconductor backplane and a light emitting element backplane on a substrate, and forming a light emitting element layer and an encapsulation layer on the light emitting element backplane. The forming of the light emitting element layer and the encapsulation layer comprises depositing a pixel electrode of each of a plurality of subpixels, depositing a pixel defining layer on the pixel electrodes to define the subpixels, etching a portion of the pixel defining layer between adjacent subpixels to form a trench surrounding at least a portion of each of the subpixels, forming heating wires on the pixel defining layer such that the heating wires may be spaced apart from each other with the trench interposed therebetween, depositing a first organic material of a first subpixel on an entire surface of the substrate, removing a portion of the first organic material deposited around the heating wires and the trench by heating the heating wires, depositing a first common electrode on the entire surface of the substrate, depositing a first encapsulation layer on the entire surface of the substrate, removing the first organic material, the first common electrode, and the first encapsulation layer deposited in a second subpixel and a third subpixel by using a first photo-patterning process and remaining the first organic material, the first common electrode, and the first encapsulation layer deposited in a portion of the trench surrounding the first subpixel, depositing a second organic material of the second subpixel on the entire surface of the substrate, removing a portion of the second organic material deposited around the heating wires and the trench by heating the heating wires, depositing a second common electrode on the entire surface of the substrate, depositing a second encapsulation layer on the entire surface of the substrate, removing the second organic material, the second common electrode, and the second encapsulation layer deposited in the first subpixel and the third subpixel by using a second photo-patterning process and remaining the second organic material, the second common electrode, and the second encapsulation layer deposited in a portion of the trench surrounding the second subpixel, depositing a third organic material of the third subpixel on the entire surface of the substrate, removing a portion of the third organic material deposited around the heating wires and the trench by heating the heating wires, depositing a third common electrode on the entire surface of the substrate, depositing a third encapsulation layer on the entire surface of the substrate, removing the third organic material, the third common electrode, and the third encapsulation layer deposited in the first subpixel and the second subpixel by using a third photo-patterning process and remaining the third organic material, the third common electrode, and the third encapsulation layer deposited in a portion of the trench surrounding the third subpixel.

A trench-free area, in which the trench is not formed, may be disposed outside each of the subpixels, and the first common electrode, the second common electrode and the third common electrode may be electrically connected through the trench-free area.

The trench between the first subpixel and the second subpixel may be divided into a first area adjacent to the first subpixel and a second area adjacent to the second subpixel, the first common electrode and the first encapsulation layer covering the first common electrode may be disposed in the first area, and the second common electrode and the second encapsulation layer covering the second common electrode may be disposed in the second area.

The trench between the second subpixel and the third subpixel may be divided into a second area adjacent to the second subpixel and a third area adjacent to the third subpixel, the second common electrode and the second encapsulation layer covering the second common electrode may be disposed in the second area, and the third common electrode and the third encapsulation layer covering the third common electrode may be disposed in the third area.

The trench between the first subpixel and the third subpixel may be divided into a first area adjacent to the first subpixel and a third area adjacent to the third subpixel, the first common electrode and the first encapsulation layer covering the first common electrode may be disposed in the first area, and the third common electrode and the third encapsulation layer covering the third common electrode may be disposed in the third area.

The first encapsulation layer, the second encapsulation layer, and the third encapsulation layer may have a same stacked structure.

The first organic material comprises a first light emitting layer that emits light of a first color having a red wavelength band, the second organic material comprises a second light emitting layer that emits light of a second color having a green wavelength band, and the third organic material comprises a third light emitting layer that emits light of a third color having a blue wavelength band.

According to an embodiment, a display device may include a pixel defining layer defining a plurality of subpixels, a pixel electrode of each subpixel disposed in an opening of the pixel defining layer, a trench formed by etching a portion of the pixel defining layer and surrounding at least a portion of each of the subpixels, heating wires disposed on the pixel defining layer and spaced apart from each other with the trench disposed between the heating wires, a first organic material covering a first pixel electrode of a first subpixel and a portion of the pixel defining layer surrounding the first pixel electrode, a first common electrode covering the first organic material and a first heating wire around the first subpixel, a first encapsulation layer covering the first common electrode and a portion of the trench around the first subpixel, a second organic material covering a second pixel electrode of a second subpixel and a portion of the pixel defining layer surrounding the second pixel electrode, a second common electrode covering the second organic material and a second heating wire around the second subpixel, a second encapsulation layer covering the second common electrode and a portion of the trench around the second subpixel, a third organic material covering a third pixel electrode of a third subpixel and a portion of the pixel defining layer surrounding the third pixel electrode, a third common electrode covering the third organic material and a third heating wire around the third subpixel, and a third encapsulation layer covering the third common electrode and a portion of the trench around the third subpixel.

A trench-free area in which the trench is not formed may be disposed outside each of the subpixels, and the first common electrode, the second common electrode and the third common electrode may be electrically connected through the trench-free area.

The trench between the first subpixel and the second subpixel may be divided into a first area adjacent to the first subpixel and a second area adjacent to the second subpixel, the first common electrode and the first encapsulation layer covering the first common electrode may be disposed in the first area, and the second common electrode and the second encapsulation layer covering the second common electrode may be disposed in the second area.

The trench between the second subpixel and the third subpixel may be divided into a second area adjacent to the second subpixel and a third area adjacent to the third subpixel, the second common electrode and the second encapsulation layer covering the second common electrode may be disposed in the second area, and the third common electrode and the third encapsulation layer covering the third common electrode may be disposed in the third area.

The trench between the first subpixel and the third subpixel may be divided into a first area adjacent to the first subpixel and a third area adjacent to the third subpixel, the first common electrode and the first encapsulation layer covering the first common electrode may be disposed in the first area, and the third common electrode and the third encapsulation layer covering the third common electrode may be disposed in the third area.

The first encapsulation layer, the second encapsulation layer, and the third encapsulation layer may have a same stacked structure.

The first organic material comprises a first light emitting layer that emits light of a first color having a red wavelength band, the second organic material comprises a second light emitting layer that emits light of a second color having a green wavelength band, and the third organic material comprises a third light emitting layer that emits light of a third color having a blue wavelength band.

The display device may further include a display panel in which alight emitting element layer is disposed on a semiconductor backplane.

According to an embodiment, a display device may include a pixel defining layer defining a plurality of subpixels, a pixel electrode of each subpixel disposed in an opening of the pixel defining layer, a trench formed by etching a portion of the pixel defining layer and surrounding at least a portion of each of the subpixels, a heating wire disposed on a bottom surface of the trench, auxiliary common electrodes disposed on the pixel defining layer and spaced apart from each other with the trench disposed between the auxiliary common electrodes, a first organic material covering a first pixel electrode of a first subpixel and a portion of the pixel defining layer surrounding the first pixel electrode, a first common electrode covering the first organic material and a first auxiliary common electrode adjacent to the first pixel electrode, a first encapsulation layer covering the first common electrode and a portion of the trench around the first subpixel, a second organic material covering a second pixel electrode of a second subpixel and a portion of the pixel defining layer surrounding the second pixel electrode, a second common electrode covering the second organic material and a second auxiliary common electrode adjacent to the second pixel electrode, a second encapsulation layer covering the second common electrode and a portion of the trench around the second subpixel, a third organic material covering a third pixel electrode of a third subpixel and a portion of the pixel defining layer surrounding the third pixel electrode, a third common electrode covering the third organic material and a third auxiliary common electrode adjacent to the third pixel electrode, and a third encapsulation layer covering the third common electrode and a portion of the trench around the third subpixel.

A trench-free area in which the trench is not formed may be disposed outside each of the subpixels, and the first auxiliary common electrode, the second auxiliary common electrode and the third auxiliary common electrode may be electrically connected through the trench-free area.

The trench between the first subpixel and the second subpixel may be divided into a first area adjacent to the first subpixel and a second area adjacent to the second subpixel, the first common electrode and the first encapsulation layer covering the first common electrode may be disposed in the first area, and the second common electrode and the second encapsulation layer covering the second common electrode may be disposed in the second area.

The trench between the second subpixel and the third subpixel may be divided into a second area adjacent to the second subpixel and a third area adjacent to the third subpixel, the second common electrode and the second encapsulation layer covering the second common electrode may be disposed in the second area, and the third common electrode and the third encapsulation layer covering the third common electrode may be disposed in the third area.

The trench between the first subpixel and the third subpixel may be divided into a first area adjacent to the first subpixel and a third area adjacent to the third subpixel, the first common electrode and the first encapsulation layer covering the first common electrode may be disposed in the first area, and the third common electrode and the third encapsulation layer covering the third common electrode may be disposed in the third area.

However, aspects of the disclosure are not restricted to those set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a head mounted display device according to an embodiment;

FIG. 2 is an exploded schematic perspective view of an example of the head mounted display device of FIG. 1;

FIG. 3 is a schematic perspective view of a head mounted display device according to an embodiment;

FIG. 4 is an exploded schematic perspective view of a display device according to an embodiment;

FIG. 5 is a schematic cross-sectional view of an example of a part of a display panel according to an embodiment;

FIG. 6 is a schematic cross-sectional view illustrating a (1-1)^{th} operation of forming heating wires according to an embodiment on a pixel defining layer;

FIG. 7 is a schematic cross-sectional view illustrating a (1-2)^{th} operation of depositing a first organic material;

FIG. 8 is a schematic cross-sectional view illustrating a (1-3)^{th} operation of removing a portion of the first organic material by using the heating wires;

FIG. 9 is a schematic cross-sectional view illustrating a (1-4)^{th} operation of depositing a first common electrode;

FIG. 10 is a schematic cross-sectional view illustrating a (1-5)^{th} operation of depositing a first encapsulation layer;

FIG. 11 is a schematic cross-sectional view illustrating a (1-6)^{th} operation of partially photo-patterning the first encapsulation layer, the first common electrode, and the first organic material;

FIG. 12 is a schematic cross-sectional view illustrating a (1-7)^{th} operation of depositing and patterning a second organic material and a third organic material in a similar manner to the (1-2)^{th} through (1-6)^{th} operations;

FIG. 13 is a schematic cross-sectional view illustrating a (2-1)^{th} operation of forming a heating wire according to an embodiment on a bottom surface of a trench;

FIG. 14 is a schematic cross-sectional view illustrating a (2-2)^{th} operation of depositing a first organic material;

FIG. 15 is a schematic cross-sectional view illustrating a (2-3)^{th} operation of removing a portion of the first organic material by using the heating wire;

FIG. 16 is a schematic cross-sectional view illustrating a (2-4)^{th} operation of depositing a first common electrode;

FIG. 17 is a schematic cross-sectional view illustrating a (2-5)^{th} operation of depositing a first encapsulation layer;

FIG. 18 is a schematic cross-sectional view illustrating a (2-6)^{th} operation of partially photo-patterning the first encapsulation layer, the first common electrode, and the first organic material;

FIG. 19 is a schematic cross-sectional view illustrating a (2-7)^{th} operation of depositing and patterning a second organic material and a third organic material in a similar manner to the (2-2)^{th} through (2-6)^{th} operations;

FIG. 20 is a layout view illustrating a part of a display panel to explain auxiliary common electrodes according to an embodiment;

FIG. 21 is a schematic cross-sectional view illustrating a (3-1)^{th} operation of forming a heating wire according to an embodiment on a bottom surface of a trench and a pixel defining layer;

FIG. 22 is a schematic cross-sectional view illustrating a (3-2)^{th} operation of depositing a first organic material;

FIG. 23 is a schematic cross-sectional view illustrating a (3-3)^{th} operation of removing a portion of the first organic material by using the heating wire;

FIG. 24 is a schematic cross-sectional view illustrating a (3-4)^{th} operation of depositing a first common electrode;

FIG. 25 is a schematic cross-sectional view illustrating a (3-5)^{th} operation of depositing a first encapsulation layer;

FIG. 26 is a schematic cross-sectional view illustrating a (3-6)^{th} operation of partially photo-patterning the first encapsulation layer, the first common electrode, and the first organic material; and

FIG. 27 is a schematic cross-sectional view illustrating a (3-7)^{th} operation of depositing and patterning a second organic material and a third organic material in a similar manner to the (3-2)^{th} through (3-6)^{th} operations.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, specific embodiments will be described with reference to the accompanying drawings.

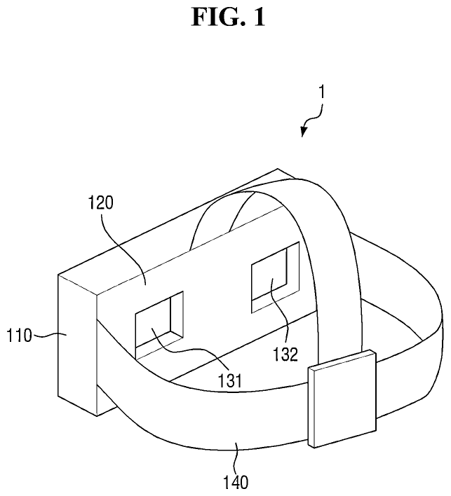

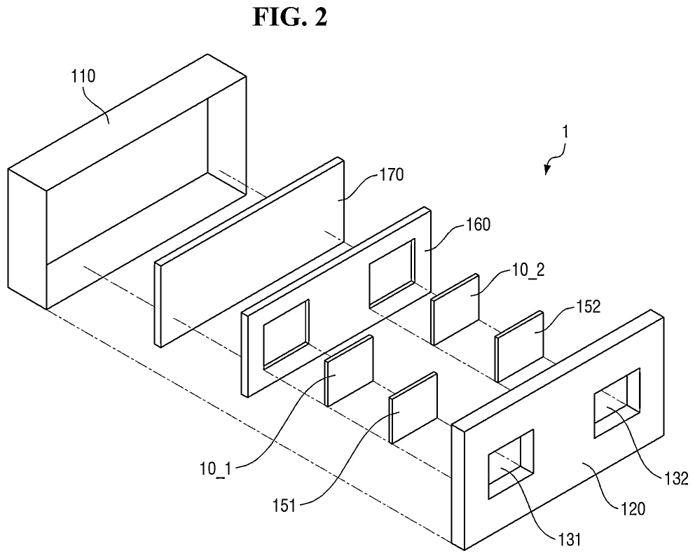

FIG. 1 is a schematic perspective view of a head mounted display device 1 according to an embodiment. FIG. 2 is an exploded schematic perspective view of an example of the head mounted display device 1 of FIG. 1.

Referring to FIGS. 1 and 2, the head mounted display device 1 may include a first display device 10_1, a second display device 10_2, a display device housing 110, a housing cover 120, a first eyepiece 131, a second eyepiece 132, a head mounted band 140, a middle frame 160, a first optical member 151, a second optical member 152, a control circuit board 170, and a connector.

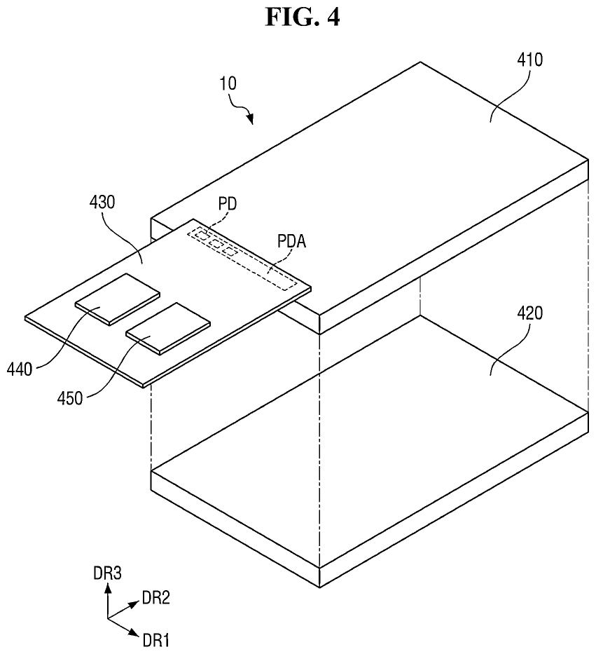

The first display device 10_1 may provide an image to a user's left eye, and the second display device 10_2 may provide an image to the user's right eye. Each of the first display device 10_1 and the second display device 10_2 may be substantially the same as a display device 10 to be described with reference to FIGS. 4 through 27. Therefore, a description of the first display device 10_1 and the second display device 10_2 will be replaced with descriptions given with reference to FIGS. 4 through 27 for descriptive convenience.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 may support and fix the first display device 10_1, the second display device 102, and the control circuit board 170.

The control circuit board 170 may be disposed between the middle frame 160 and the display device housing 110. The control circuit board 170 may be connected to the first display device 10_1 and the second display device 10_2 through the connector. The control circuit board 170 may convert an image source received from the outside into digital video data and transmit the digital video data to the first display device 10_1 and the second display device 102 through the connector.

The control circuit board 170 may transmit the digital video data corresponding to a left-eye image, which is optimized for a user's left eye, to the first display device 10_1 and transmit the digital video data corresponding to a right-eye image, which is optimized for the user's right eye, to the second display device 10_2. In another example, the control circuit board 170 may transmit the same digital video data to the first display device 10_1 and the second display device 10_2.

The display device housing 110 may accommodate the first display device 10_1, the second display device 10_2, the middle frame 160, the first optical member 151, the second optical member 152, the control circuit board 170, and the connector. The housing cover 120 may cover an open surface of the display device housing 110. The housing cover 120 may include the first eyepiece 131, on which a user's left eye may be disposed, and the second eyepiece 132, on which the user's right eye is disposed. Although the first eyepiece 131 and the second eyepiece 132 are disposed separately in FIGS. 1 and 2, embodiments are not limited thereto. The first eyepiece 131 and the second eyepiece 132 may also be combined with each other.

The first eyepiece 131 may be aligned with the first display device 10_1 and the first optical member 151, and the second eyepiece 132 may be aligned with the second display device 10_2 and the second optical member 152. Therefore, a user may view an image of the first display device 10_1, which is enlarged as a virtual image by the first optical member 151, through the first eyepiece 131 and may view an image of the second display device 10_2, which is enlarged as a virtual image by the second optical member 152, through the second eyepiece 132.

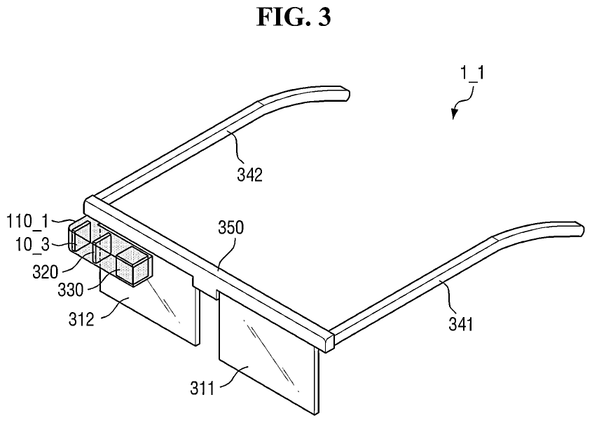

The head mounted band 140 may fix the display device housing 110 to a user's head so that the first eyepiece 131 and the second eyepiece 132 of the housing cover 120 may be held on the user's left and right eyes, respectively. In case that the display device housing 120 is implemented to be lightweight and small, the head mounted display device 1 may include an eyeglass frame as illustrated in FIG. 3 instead of the head mounted band 140.

For example, the head mounted display device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal. The wireless communication module may be a 5G communication module, a 4G communication module, a Wi-Fi module, or a Bluetooth module.

FIG. 3 is a schematic perspective view of a head mounted display device 1_1 according to an embodiment.

Referring to FIG. 3, the head mounted display device 1_1 may be a display device in the form of glasses in which a display device housing 110_1 is implemented to be lightweight and small. The head mounted display device 1_1 may include a display device 10_3, a left-eye lens 311, a right-eye lens 312, a support frame 350, eyeglass frame legs 341 and 342, an optical member 320, an optical path conversion member 330, and the display device housing 110_1.

The display device 10_3 illustrated in FIG. 3 is substantially the same as a display device 10 to be described with reference to FIGS. 4 through 27. Therefore, a description of the display device 10_3 will be replaced with the descriptions given with reference to FIGS. 4 through 27 for descriptive convenience.

The display device housing 110_1 may include the display device 10_3, the optical member 320, and the optical path conversion member 330. An image displayed on the display device 10_3 may be enlarged by the optical member 320, may have its optical path converted by the optical path conversion member 330, and may be provided to a user's right eye through the right-eye lens 312. Accordingly, the user may view, through the right eye, an augmented reality image, which is generated by combining a virtual image displayed on the display device 10_3 and a real image viewed through the right-eye lens 312.

Although the display device housing 110_1 is disposed at a right end portion of the support frame 350 in FIG. 3, embodiments are not limited thereto. For example, the display device housing 110_1 may also be disposed at a left end portion of the support frame 350. For example, an image of the display device 103 may be provided to a user's left eye. In another example, the display device housing 110_1 may be disposed at both the left and right ends of the support frame 350. For example, the user may view an image displayed on the display device 10_3 through both the left and right eyes.

FIG. 4 is an exploded schematic perspective view of a display device 10 according to an embodiment.

Referring to FIG. 4, the display device 10 may be a device for displaying moving images or still images. The display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. In another example, the display device 10 may be applied to smart watches, watch phones, and head mounted displays for implementing virtual reality and augmented reality.

The display device 10 may include a display panel 410, a heat dissipation layer 420, a circuit board 430, a driving circuit 440, and a power supply circuit 450.

The display panel 410 may have a planar shape similar to a quadrangle. For example, the display panel 410 may have a planar shape similar to a quadrangle having short sides in a first direction DR1 and long sides in a second direction DR2 intersecting the first direction DR1. In the display panel 410, each corner portion where a short side extending in the first direction DR1 meets a long side extending in the second direction DR2 may be rounded with a selectable curvature or may be right-angled. The planar shape of the display panel 410 is not limited to a quadrangular shape, but may also be similar to another polygonal shape, a circular shape, or an oval shape. The planar shape of the display device 10 may follow the planar shape of the display panel 410, but embodiments are not limited thereto.

The display panel 410 may include a display area that displays an image and a non-display area that does not display an image.

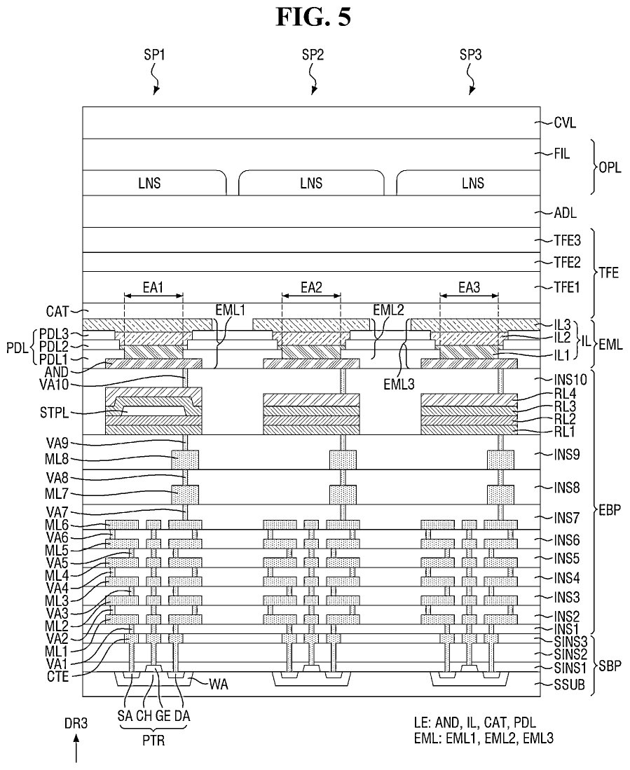

The display area may include pixels, and each of the pixels may include subpixels SP1 through SP3 (see FIG. 5). The subpixels SP1 through SP3 may include pixel transistors. The pixel transistors may be formed by a semiconductor process and may be disposed on a substrate (or semiconductor substrate) SSUB (see FIG. 5). For example, the pixel transistors may be formed as complementary metal oxide semiconductors (CMOS).

The heat dissipation layer 420 may overlap the display panel 410 in a third direction DR3 which is a thickness direction of the display panel 410. The heat dissipation layer 420 may be disposed on a surface, e.g., a back surface (or rear surface) of the display panel 410. The heat dissipation layer 420 may dissipate heat generated in the display panel 410. The heat dissipation layer 420 may include a metal layer having high thermal conductivity, such as graphite, silver (Ag), copper (Cu), or aluminum (Al).

The circuit board 430 may be electrically connected to pads PD in a pad area PDA of the display panel 410 by using a conductive adhesive member such as an anisotropic conductive film. The circuit board 430 may be a flexible printed circuit board made of a flexible material or may be a flexible film. Although the circuit board 430 is unfolded in FIG. 4, the circuit board 430 may also be bent. For example, an end portion of the circuit board 430 may be disposed on the back surface (or rear surface) of the display panel 410. The end portion of the circuit board 430 may be opposite to another end portion of the circuit board 430 which is connected to the pads PD in the pad area PDA of the display panel 410 by using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate panel driving voltages according to a power supply voltage received from the outside. For example, the power supply circuit 450 may generate a first driving voltage (e.g., low power voltage), a second driving voltage (e.g., high power voltage) and a third driving voltage (e.g., reference voltage) and supply them to the display panel 410.

Each of the driving circuit 440 and the power supply circuit 450 may be formed as an integrated circuit and attached to a surface of the circuit board 430.

FIG. 5 is a schematic cross-sectional view of an example of a part of a display panel 410 according to an embodiment. For example, FIG. 5 illustrates a partial cross-sectional structure of a display area including subpixels SP1 through SP3.

Referring to FIG. 5, the display panel 410 may include a semiconductor backplane SBP, a light emitting element backplane EBP, a light emitting element layer EML, an encapsulation layer TFE, an optical layer OPL, a cover layer CVL, and a polarizer.

The semiconductor backplane SBP may include a substrate (e.g., semiconductor substrate) SSUB including pixel transistors PTR, semiconductor insulating layers covering the pixel transistors PTR, and contact terminals CTE electrically connected to the pixel transistors PTR.

The substrate SSUB may be a silicon substrate, a germanium substrate, or a silicon-germanium substrate. The substrate SSUB may be a substrate doped with first-type impurities. Well areas WA may be disposed on an upper surface of the substrate SSUB. The well areas WA may be areas doped with second-type impurities. The second-type impurities may be different from the first-type impurities. For example, in case that the first-type impurities are p-type impurities (or p-type dopants), the second-type impurities may be n-type impurities (or n-type dopants). In case that the first-type impurities are n-type impurities, the second-type impurities may be p-type impurities.

Each of the well areas WA may include a source region SA corresponding to a source electrode of a pixel transistor PTR, a drain region DA corresponding to a drain electrode, and a channel region CH disposed between the source region SA and the drain region DA.

Each of the source region SA and the drain region DA may be an area doped with the first-type impurities. A gate electrode GE of each pixel transistor PTR may overlap a well area WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the well areas WA may further include a first lightly doped impurity area disposed between the channel region CH and the source region SA and a second lightly doped impurity area disposed between the channel region CH and the drain region DA. The first lightly doped impurity area may be an area having a lower impurity concentration than the source region SA. The second lightly doped impurity area may be an area having a lower impurity concentration than the drain region DA. A distance between the source region SA and the drain region DA may be increased by the first lightly doped impurity area and the second lightly doped impurity area. Accordingly, a length of the channel region CH of each pixel transistor PTR may increase, thereby preventing punch-through phenomena and hot carrier phenomena caused by a short channel.

A first semiconductor insulating layer SINS1 may be disposed on the substrate SSUB. The first semiconductor insulating layer SINS1 may be a silicon carbon nitride (SiCₓN_{y}) or silicon oxide (SiOₓ)-based inorganic layer, but embodiments are not limited thereto.

A second semiconductor insulating layer SINS2 may be disposed on the first semiconductor insulating layer SINS1. The second semiconductor insulating layer SINS2 may be a silicon oxide (SiOₓ)-based inorganic layer, but embodiments are not limited thereto.

The contact terminals CTE may be disposed on the second semiconductor insulating layer SINS2. Each of the contact terminals CTE may be connected to any one of the gate electrode GE, the source region SA, and the drain region DA of a pixel transistor PTR through a hole penetrating the first semiconductor insulating layer SINS1 and the second semiconductor insulating layer SINS2. The contact terminals CTE may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above.

A third semiconductor insulating layer SINS3 may be disposed on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOₓ)-based inorganic layer, but embodiments are not limited thereto.

The substrate SSUB may be replaced with a glass substrate or a polymer resin substrate such as polyimide (PI). For example, thin-film transistors may be disposed on the glass substrate or the polymer resin substrate. The glass substrate may be a rigid substrate that is not bent, and the polymer resin substrate may be a flexible substrate that is able to be bent or curved.

The light emitting element backplane EBP may include first through eighth metal layers ML1 through ML8, reflective electrodes RL1 through RL4, via layers VA1 through VA10, and a step layer STPL. For example, the light emitting element backplane EBP may include interlayer insulating layers INS1 through INS10 disposed between the first through eighth metal layers ML1 through ML8.

The first through eighth metal layers ML1 through ML8 function to implement the circuit of a first subpixel SP1 by connecting the contact terminals CTE exposed in the semiconductor backplane SBP. For example, only first through sixth transistors may be formed in the semiconductor backplane SBP, and the connection of the first through sixth transistors and a first capacitor and a second capacitor may be achieved through the first through eighth metal layers ML1 through ML8. For example, the connection between a drain region corresponding to a drain electrode of the fourth transistor and a source region corresponding to a source electrode of the fifth transistor and a pixel electrode AND of a light emitting element LE may be also achieved through the first through eighth metal layers ML1 through ML8.

A first interlayer insulating layer INS1 may be disposed on the semiconductor backplane SBP. First via layers VA1 may penetrate the first interlayer insulating layer INS1 and may be respectively connected to the contact terminals CTE exposed in the semiconductor backplane SBP. The first metal layers ML1 may be disposed on the first interlayer insulating layer INS1 and may be connected to the first via layers VA1, respectively.

A second interlayer insulating layer INS2 may be disposed on the first interlayer insulating layer INS1 and the first metal layers ML1. Second via layers VA2 may penetrate the second interlayer insulating layer INS2 and may be connected to the exposed first metal layers ML1, respectively. The second metal layers ML2 may be disposed on the second interlayer insulating layer INS2 and may be connected to the second via layers VA2, respectively.

A third interlayer insulating layer INS3 may be disposed on the second interlayer insulating layer INS2 and the second metal layers ML2. Third via layers VA3 may penetrate the third interlayer insulating layer INS3 and may be connected to the exposed second metal layers ML2, respectively. The third metal layers ML3 may be disposed on the third interlayer insulating layer INS3 and may be connected to the third via layers VA3, respectively.

A fourth interlayer insulating layer INS4 may be disposed on the third interlayer insulating layer INS3 and the third metal layers ML3. Fourth via layers VA4 may penetrate the fourth interlayer insulating layer INS4 and may be connected to the exposed third metal layers ML3, respectively. The fourth metal layers ML4 may be disposed on the fourth interlayer insulating layer INS4 and may be connected to the fourth via layers VA4, respectively.

A fifth interlayer insulating layer INS5 may be disposed on the fourth interlayer insulating layer INS4 and the fourth metal layers ML4. Fifth via layers VA5 may penetrate the fifth interlayer insulating layer INS5 and may be connected to the exposed fourth metal layers ML4, respectively. The fifth metal layers ML5 may be disposed on the fifth interlayer insulating layer INS5 and may be connected to the fifth via layers VA5, respectively.

A sixth interlayer insulating layer INS6 may be disposed on the fifth interlayer insulating layer INS5 and the fifth metal layers ML5. Sixth via layers VA6 may penetrate the sixth interlayer insulating layer INS6 and may be connected to the exposed fifth metal layers ML5, respectively. The sixth metal layers ML6 may be disposed on the sixth interlayer insulating layer INS6 and may be connected to the sixth via layers VA6, respectively.

A seventh interlayer insulating layer INS7 may be disposed on the sixth interlayer insulating layer INS6 and the sixth metal layers ML6. Seventh via layers VA7 may penetrate the seventh interlayer insulating layer INS7 and may be connected to the exposed sixth metal layers ML6, respectively. The seventh metal layers ML7 may be disposed on the seventh interlayer insulating layer INS7 and may be connected to the seventh via layers VA7, respectively.

An eighth interlayer insulating layer INS8 may be disposed on the seventh interlayer insulating layer INS7 and the seventh metal layers ML7. Eighth via layers VA8 may penetrate the eighth interlayer insulating layer INS8 and may be connected to the exposed seventh metal layers ML7, respectively. The eighth metal layers ML8 may be disposed on the eighth interlayer insulating layer INS8 and may be connected to the eighth via layers VA8, respectively.

The first through eighth metal layers ML1 through ML8 and the first through eighth via layers VA1 through VA8 may be made of substantially the same material. The first through eighth metal layers ML1 through ML8 and the first through eighth via layers VA1 through VA8 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above. The first through eighth via layers VA1 through VA8 may be made of substantially the same material. Each of the first through eighth interlayer insulating layers INS1 through INS8 may be a silicon oxide (SiOₓ)-based inorganic layer, but embodiments are not limited thereto.

A thickness of the first metal layers ML1, a thickness of the second metal layers ML2, a thickness of the third metal layers ML3, a thickness of the fourth metal layers ML4, a thickness of the fifth metal layers ML5, and a thickness of the sixth metal layers ML6 may each be greater than a thickness of the first via layers VA1, a thickness of the second via layers VA2, a thickness of the third via layers VA3, a thickness of the fourth via layers VA4, a thickness of the fifth via layers VA5, and a thickness of the sixth via layers VA6. The thickness of the second metal layers ML2, the thickness of the third metal layers ML3, the thickness of the fourth metal layers ML4, the thickness of the fifth metal layers ML5, and the thickness of the sixth metal layers ML6 may each be greater than the thickness of the first metal layers ML1. The thickness of the second metal layers ML2, the thickness of the third metal layers ML3, the thickness of the fourth metal layers ML4, the thickness of the fifth metal layers ML5, and the thickness of the sixth metal layers ML6 may be substantially the same. For example, the thickness of the first metal layers ML1 may be about 1,360 Å, the thickness of the second metal layers ML2, the thickness of the third metal layers ML3, the thickness of the fourth metal layers ML4, the thickness of the fifth metal layers ML5 and the thickness of the sixth metal layers ML6 may each be about 1,440 Å, and the thickness of the first via layers VA1, the thickness of the second via layers VA2, the thickness of the third via layers VA3, the thickness of the fourth via layers VA4, the thickness of the fifth via layers VA5 and the thickness of the sixth via layers VA6 may each be about 1,150 Å.

A thickness of the seventh metal layers ML7 and a thickness of the eighth metal layers ML8 may each be greater than the thickness of the first metal layers ML1, the thickness of the second metal layers ML2, the thickness of the third metal layers ML3, the thickness of the fourth metal layers ML4, the thickness of the fifth metal layers ML5, and the thickness of the sixth metal layer ML6. The thickness of the seventh metal layers ML7 and the thickness of the eighth metal layers ML8 may each be greater than a thickness of the seventh via layers VA7 and a thickness of the eighth via layers VA8. The thickness of the seventh via layers VA7 and the thickness of the eighth via layers VA8 may each be greater than the thickness of the first via layers VA1, the thickness of the second via layers VA2, the thickness of the third via layers VA3, the thickness of the fourth via layers VA4, the thickness of the fifth via layers VA5, and the thickness of the sixth via layers VA6. The thickness of the seventh metal layers ML7 and the thickness of the eighth metal layers ML8 may be substantially the same as each other. For example, the thickness of the seventh metal layers ML7 and the thickness of the eighth metal layers ML8 may each be about 9,000 Å. The thickness of the seventh via layers VA7 and the thickness of the eighth via layers VA8 may each be about 6,000 Å.

A ninth interlayer insulating layer INS9 may be disposed on the eighth interlayer insulating layer INS8 and the eighth metal layers ML8. The ninth interlayer insulating layer INS9 may be a silicon oxide (SiOₓ)-based inorganic layer, but embodiments are not limited thereto.

Ninth via layers VA9 may penetrate the ninth interlayer insulating layer INS9 and may be connected to the exposed eighth metal layers ML8, respectively. The ninth via layers VA9 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above. A thickness of the ninth via layers VA9 may be about 16,500 Å.

First reflective electrodes RL1 may be disposed on the ninth interlayer insulating layer INS9 and may be connected to the ninth via layers VA9, respectively. The first reflective electrodes RL1 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above.

Second reflective electrodes RL2 may be disposed on the first reflective electrodes RL1, respectively. The second reflective electrodes RL2 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above. For example, the second reflective electrodes RL2 may be titanium nitride (TiN).

In the first subpixel SP1, the step layer STPL may be disposed on a second reflective electrode RL2. The step layer STPL may not be disposed in a second subpixel SP2 and a third subpixel SP3. A thickness of the step layer STPL may be determined in consideration of the wavelength of light of a first color and a distance from a first light emitting layer EML1 to a fourth reflective electrode RL4 so as to perform the reflection of the light of the first color emitted from the first light emitting layer EML1 of the first subpixel SP1. The step layer STPL may be a silicon carbon nitride (SiCₓN_{y}) or silicon oxide (SiOₓ)-based inorganic layer, but embodiments are not limited thereto. The thickness of the step layer STPL may be about 400 Å.

In the first subpixel SP1, a third reflective electrode RL3 may be disposed on the second reflective electrode RL2 and the step layer STPL. In each of the second subpixel SP2 and the third subpixel SP3, the third reflective electrode RL3 may be disposed on the second reflective electrode RL2. The third reflective electrodes RL3 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above.

In another example, at least one of the first through third reflective electrodes RL1 through RL3 may be omitted.

Fourth reflective electrodes RL4 may be disposed on the third reflective electrodes RL3, respectively. The fourth reflective electrodes RL4 may be layers that reflect light from first through third light emitting layers EML1, EML2, and EML3, which are respectively disposed in the first through third subpixels SP1, SP2, and SP3. The fourth reflective electrodes RL4 may include a metal having high reflectivity to perform reflection of light. The fourth reflective electrodes RL4 may be made of aluminum (Al), a stacked structure (Ti/Al/Ti) of aluminum and titanium, a stacked structure (ITO/Al/ITO) of aluminum and indium tin oxide, an Ag—Pd—Cu (APC) alloy which is an alloy of silver (Ag), palladium (Pd) and copper (Cu), or a stacked structure (ITO/APC/ITO) of an APC alloy and indium tin oxide, but embodiments are not limited thereto. A thickness of each of the fourth reflective electrodes RL4 may be about 850 Å.

A tenth interlayer insulating layer INS10 may be disposed on the ninth interlayer insulating layer INS9 and the fourth reflective electrodes RL4. The tenth interlayer insulating layer INS10 may be a silicon oxide (SiOₓ)-based inorganic layer, but embodiments are not limited thereto.

Tenth via layers VA10 may penetrate the tenth interlayer insulating layer INS10 and may be connected to the exposed fourth reflective electrodes RL4, respectively. The tenth via layers VA10 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above. Due to the step layer STPL, a thickness of a tenth via layer VA10 in the first subpixel SP1 may be smaller than a thickness of a tenth via layer VA10 in each of the second subpixel SP2 and the third subpixel SP3. For example, the thickness of the tenth via layer VA10 in the first subpixel SP1 may be about 800 Å, and the thickness of the tenth via layer VA10 in each of the second subpixel SP2 and the third subpixel SP3 may be about 1,200 Å.

The light emitting element layer EML (e.g., EML1, EML2, and EML3) may be disposed on the light emitting element backplane EBP. The light emitting element layer EML may include light emitting elements LE, each including a pixel electrode AND, an intermediate layer IL and a common electrode CAT, and a pixel defining layer PDL. The pixel electrode AND may also be referred to as an “anode” or a “first electrode.” The common electrode CAT may also be referred to as a “cathode” or a “second electrode.”

The pixel electrode AND (e.g., AND1, AND2, and AND3) of each of the light emitting elements LE may be disposed on the tenth interlayer insulating layer INS10 and may be connected to a tenth via layer VA10. The pixel electrode AND (e.g., AND1, AND2, and AND3) of each of the light emitting elements LE may be connected to the drain region DA or the source region SA of a pixel transistor PTR through a tenth via layer VA10, the first through fourth reflective electrodes RL1 through RL4, the first through ninth via layers VA1 through VA9, the first through eighth metal layers ML1 through ML8, and a contact terminal CTE. The pixel electrode AND of each of the light emitting elements LE may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same materials above. For example, the pixel electrode AND of each of the light emitting elements LE may be titanium nitride (TiN).

The pixel defining layer PDL may be disposed on a portion of the pixel electrode AND of each of the light emitting elements LE. The pixel defining layer PDL may cover edge portions of the pixel electrode AND of each of the light emitting elements LE. The pixel defining layer PDL defines first through third emission areas EA1 through EA3.

The first emission area EA1 may be defined as an area in the first subpixel SP1 where the pixel electrode AND, the intermediate layer IL, and the common electrode CAT are sequentially stacked to emit light. The second emission area EA2 may be defined as an area in the second subpixel SP2 where the pixel electrode AND, the intermediate layer IL, and the common electrode CAT are sequentially stacked to emit light. The third emission area EA3 may be defined as an area in the third subpixel SP3 where the pixel electrode AND, the intermediate layer IL, and the common electrode CAT are sequentially stacked to emit light.

The pixel defining layer PDL may include first through third pixel defining layers PDL1 through PDL3. The first pixel defining layer PDL1 may be disposed on the edge portions of the pixel electrode AND of each of the light emitting elements LE, the second pixel defining layer PDL2 may be disposed on the first pixel defining layer PDL1, and the third pixel defining layer PDL3 may be disposed on the second pixel defining layer PDL2. Each of the first pixel defining layer PDL1, the second pixel defining layer PDL2, and the third pixel defining layer PDL3 may be a silicon oxide (SiOₓ)-based inorganic layer, but embodiments are not limited thereto. A thickness of the first pixel defining layer PDL1, a thickness of the second pixel defining layer PDL2, and a thickness of the third pixel defining layer PDL3 may each be about 500 Å.

The intermediate layer IL may include a first intermediate layer IL1, a second intermediate layer IL2, and a third intermediate layer IL3.

The intermediate layer IL may have a tandem structure including intermediate layers IL1 through IL3 that emit different lights. For example, the intermediate layer IL may include the first intermediate layer IL1 that emits light of a first color, the second intermediate layer IL2 that emits light of a third color, and the third intermediate layer IL3 that emits light of a second color. The first intermediate layer IL1, the second intermediate layer IL2, and the third intermediate layer IL3 may be sequentially stacked.

The first intermediate layer IL1 may have a structure in which a first hole transport layer, a first organic light emitting layer emitting light of the first color, and a first electron transport layer are sequentially stacked. The second intermediate layer IL2 may have a structure in which a second hole transport layer, a second organic light emitting layer emitting light of the third color, and a second electron transport layer are sequentially stacked. The third intermediate layer IL3 may have a structure in which a third hole transport layer, a third organic light emitting layer emitting light of the second color, and a third electron transport layer are sequentially stacked.

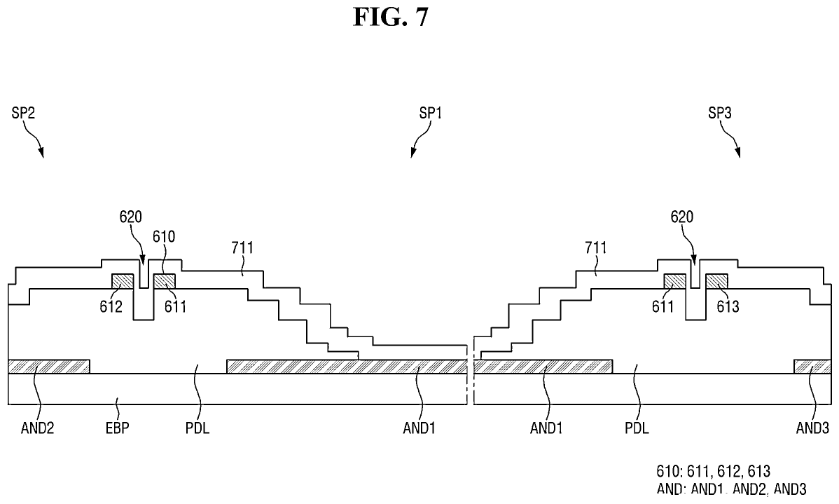

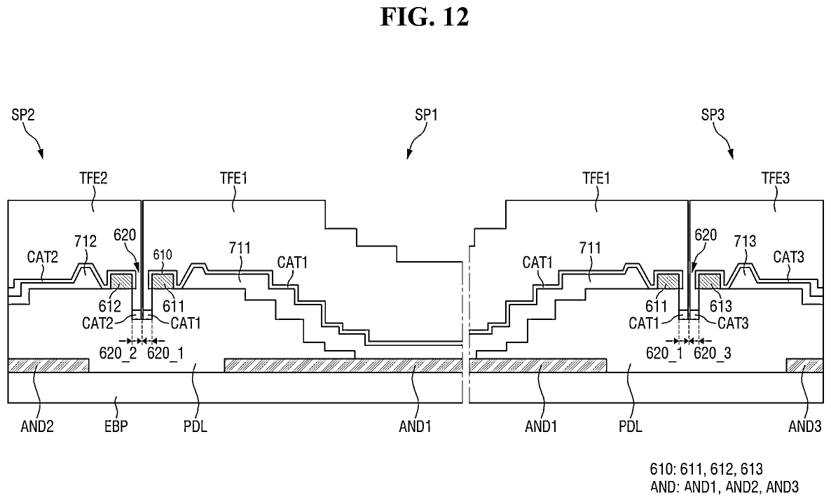

According to an embodiment, the intermediate layer IL may have an organic light emitting layer that emits light of a different color in each subpixel. For example, the intermediate layer IL may include a first organic material 711 (see FIG. 7) disposed in the first subpixel SP1, a second organic material 712 (see FIG. 12) disposed in the second subpixel SP2, and a third organic material 713 disposed in the third subpixel SP3. The first organic material 711 may include a first light emitting layer that emits light of a first color in a red wavelength band. The second organic material 712 may include a second light emitting layer that emits light of a second color in a green wavelength band. The third organic material 713 may include a third light emitting layer that emits light of a third color in a blue wavelength band.

The intermediate layer IL may cover the pixel electrode AND in each opening of the pixel defining layer PDL and cover the pixel defining layer PDL between neighboring subpixels (or adjacent subpixels) SP1 through SP3, but may be disconnected around a heating wire (e.g., 610 in FIG. 7). Accordingly, the display device 10 may prevent color interference caused by leakage current.

The color interference phenomenon refers to, for example, a phenomenon in which the first subpixel SP1 adjacent to the third subpixel SP3 is unintentionally turned on in case that the third subpixel SP3 emits blue light. The color interference phenomenon may occur due to the leakage current and may occur in a condition that the third subpixel SP3 and the first subpixel SP1, which have a large difference in pixel driving voltage, are adjacent to each other. For example, the leakage current refers to a phenomenon in which a portion of the driving current is transmitted to the first subpixel SP1 through at least some conductive layers of the intermediate layer IL in case that a driving current is supplied to the light emitting element LE of the third subpixel SP3 to turn on the third subpixel SP3. In case that the leakage current occurs, the first subpixel SP1 may be unintentionally turned on while the third subpixel SP3 is turned on.

The common electrode CAT may be disposed on the intermediate layer IL. The common electrode CAT may be made of a transparent conductive material (TCO) that is capable of transmitting light, such as indium tin oxide (ITO) or indium zinc oxide (IZO), or a semi-transmissive conductive material such as magnesium (Mg), silver (Ag) or an alloy of Mg and Ag.

The encapsulation layer TFE may be disposed on the light emitting element layer EML. The encapsulation layer TFE may include one or more inorganic layers TFE1 and TFE2 to prevent permeation of oxygen or moisture into the light emitting element layer EML. For example, the encapsulation layer TFE may include at least one organic layer to protect the light emitting element layer EML from foreign substances such as dust. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be disposed on the common electrode CAT, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from silicon nitride (SiNx), silicon oxynitride (SiOxNy), silicon oxide (SiOₓ), titanium oxide (TiOx), and aluminum oxide (AlOx) layers are alternately stacked. The encapsulating organic layer TFE2 may be a monomer. In another example, the encapsulating organic layer TFE2 may be an organic layer such as acryl resin, epoxy resin, phenolic resin, polyamide resin, or polyimide resin.

An adhesive layer ADL (in, e.g., FIG. 5) may be a layer for bonding the encapsulation layer TFE and the optical layer OPL together. The adhesive layer ADL may be a double-sided adhesive member. For example, the adhesive layer ADL may be a transparent adhesive member such as a transparent adhesive or a transparent adhesive resin.

The optical layer OPL may include lenses LNS and a filling layer FIL.

Each of the lenses LNS may be a structure for increasing the ratio of light directed to the front of the display device 10. Each of the lenses LNS may have an upwardly convex cross-sectional shape.

The filling layer FIL may be disposed on the lenses LNS. The filling layer FIL may have a selectable refractive index so that light may travel in the third direction DR3 at an interface between the lenses LNS and the filling layer FIL. For example, the filling layer FIL may be a planarization layer. The filling layer FIL may be an organic layer such as acryl resin, epoxy resin, phenolic resin, polyamide resin, or polyimide resin.

The cover layer CVL may be disposed on the filling layer FIL. The cover layer CVL may be a glass substrate or a polymer resin such as resin. In case that the cover layer CVL is a glass substrate, the cover layer CVL may be attached onto the filling layer FIL. For example, the filling layer FIL may function to bond the cover layer CVL. In case that the cover layer CVL is a glass substrate, the cover layer CVL may function as an encapsulation substrate. In case that the cover layer CVL is a polymer resin such as resin, the cover layer CVL may be disposed (e.g., directly disposed) on the filling layer FIL.

The polarizer may be disposed on a surface of the cover layer CVL. The polarizer may be a structure for preventing visibility reduction due to reflection of external light. The polarizer may include a linear polarizer and a phase retardation film. For example, the phase retardation film may be a quarter-wave plate (λ/4 plate), but embodiments are not limited thereto.

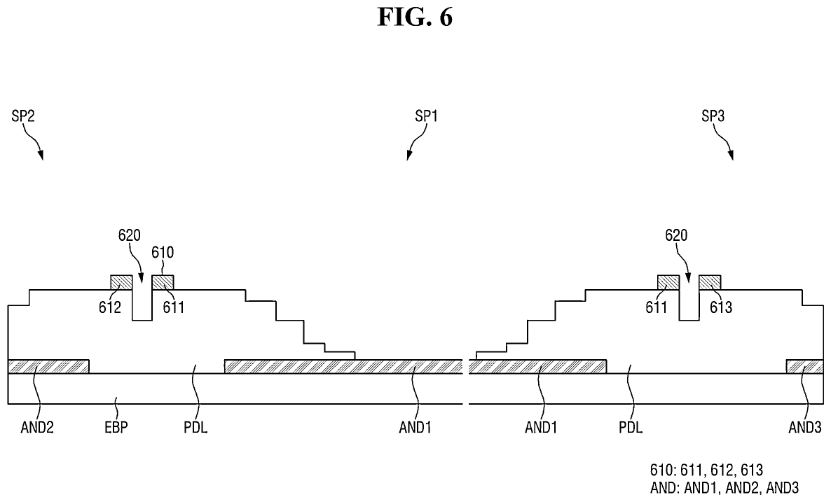

Hereinafter, display devices 10 and methods of manufacturing the display devices 10 according to embodiments will be described in detail with reference to FIGS. 6 through 27. In the display devices 10 and the methods of manufacturing the display devices 10 according to embodiments, leakage current may be prevented by depositing and patterning an organic material for each subpixel using a heating wire 610, and the encapsulation performance of the organic material may be improved using a trench 620.

FIGS. 6 through 12 are schematic cross-sectional views illustrating a method of manufacturing a display panel 410 according to an embodiment. FIGS. 6 through 12 illustrate the display panel 410 of a display device 10, a semiconductor backplane SBP disposed on the substrate SSUB, and a light emitting element backplane EBP disposed on the semiconductor backplane SBP. A description of the unillustrated elements will be replaced with the description given with reference to FIG. 5 for descriptive convenience.

The method of manufacturing the display panel 410 in which an organic material is deposited and patterned for each subpixel by using heating wires 610 will now be described with reference to FIGS. 6 through 12.

FIG. 6 is a schematic cross-sectional view illustrating a (1-1)^{th} operation of forming heating wires 610 (e.g., 611, 612, and 613) according to an embodiment on a pixel defining layer PDL.

Referring to FIG. 6, in the (1-1)^{th} operation, the substrate SSUB of the display panel 410 may be prepared. The substrate SSUB may be a substrate SSUB.

For example, the semiconductor backplane SBP and the light emitting element backplane EBP described with reference to FIG. 5 may be sequentially formed on the substrate SSUB.

For example, a pixel electrode AND (e.g., AND1, AND2, and AND3) of each of subpixels SP1 through SP3 may be deposited.

For example, the pixel defining layer PDL may be deposited on the pixel electrodes AND to define the subpixels SP1 through SP3. The pixel defining layer PDL may be patterned to expose a portion of the pixel electrode AND of each of the subpixels SP1 through SP3. For example, the pixel electrode AND of each of the subpixels SP1 through SP3 may be exposed through an opening of the pixel defining layer PDL during a process.

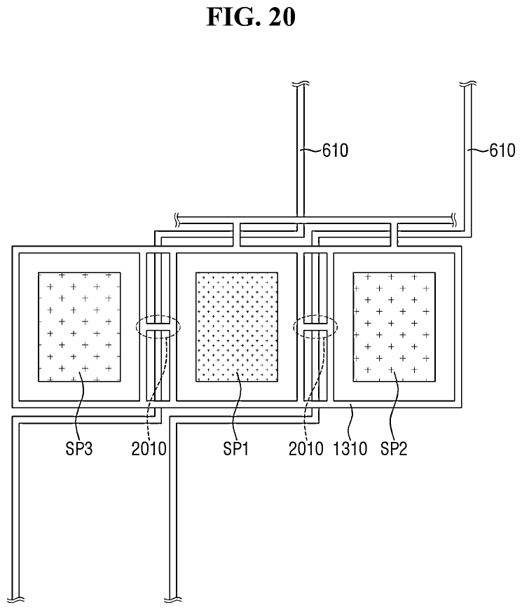

For example, a portion of the pixel defining layer PDL between neighboring subpixels (or adjacent subpixels) SP1 through SP3 may be etched to form a trench 620 surrounding at least a portion of each of the subpixels SP1 through SP3. For example, the trench 620 may not completely surround each of the subpixels SP1 through SP3 and may not be formed in some areas. An area in which the trench 620 is not formed may be referred to as a “trench-free area 2010 (see FIG. 20).” The trench-free area 2010 may be an area for preventing disconnection of common electrodes CAT from each other.

For example, the heating wires 610 may be formed on the pixel defining layer PDL. The heating wires 610 may surround at least a portion of each of the subpixels SP1 through SP3. The heating wires 610 may be spaced apart from each other with the trench 620 interposed between the heating wires 610. For example, a pair of heating wires 610 may be disposed between neighboring subpixels (or adjacent subpixels) SP1 through SP3 and may be spaced apart from each other with the trench 620 interposed between the pair of heating wires 610. The heating wires 610 may receive a joule heating voltage from the outside and may be heated to a specified temperature (e.g., about 400° C.) or higher based on the received joule heating voltage. The heating wires 610 function to remove an organic material deposited around the heating wires 610, as will be described later.

FIG. 7 is a schematic cross-sectional view illustrating a (1-2)^{th} operation of depositing a first organic material 711. Referring to FIG. 7, in the (1-2)^{th} operation, the first organic material 711 of a first subpixel SP1 may be deposited on the entire surface of the substrate SSUB. The first organic material 711 may include a first light emitting layer that emits light of a first color in a red wavelength band. The first organic material 711 may be commonly deposited not only in the first subpixel SP1 for displaying the first color, but also in a second subpixel SP2 for displaying a second color and a third subpixel SP3 for displaying a third color.

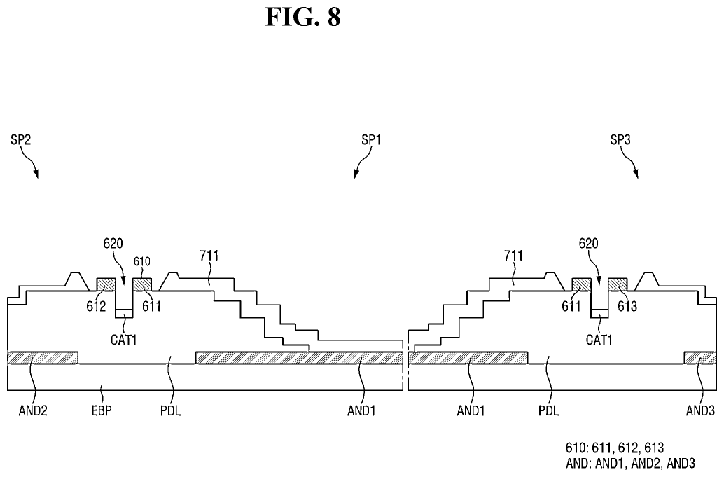

FIG. 8 is a schematic cross-sectional view illustrating a (1-3)^{th} operation of removing a portion of the first organic material 711 by using the heating wires 610. Referring to FIG. 8, in the (1-3)^{th} operation, a joule heating voltage may be applied to the heating wires 610, and the first organic material 711 disposed around the heating wires 610 may be removed using the heated heating wires 610. For example, the first organic material 711 disposed around the heating wires 610, on the heating wires 610, and in the trench 620 may be removed.

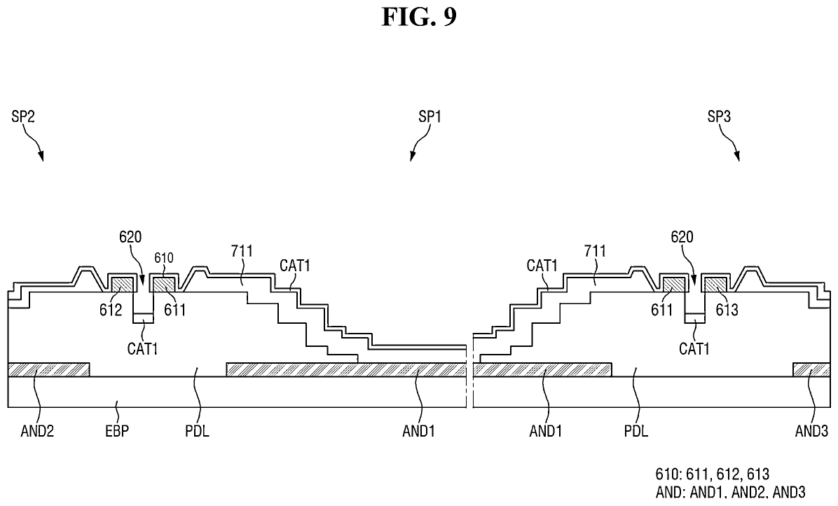

FIG. 9 is a schematic cross-sectional view illustrating a (1-4)^{th} operation of depositing a first common electrode CAT1. Referring to FIG. 9, in the (1-4)^{th} operation, the first common electrode CAT1 may be deposited on the entire surface of the substrate SSUB. The first common electrode CAT1 may be deposited on the first organic material 711, the pixel defining layer PDL disposed around the heating wires 610, the heating wires 610, and the trench 620.

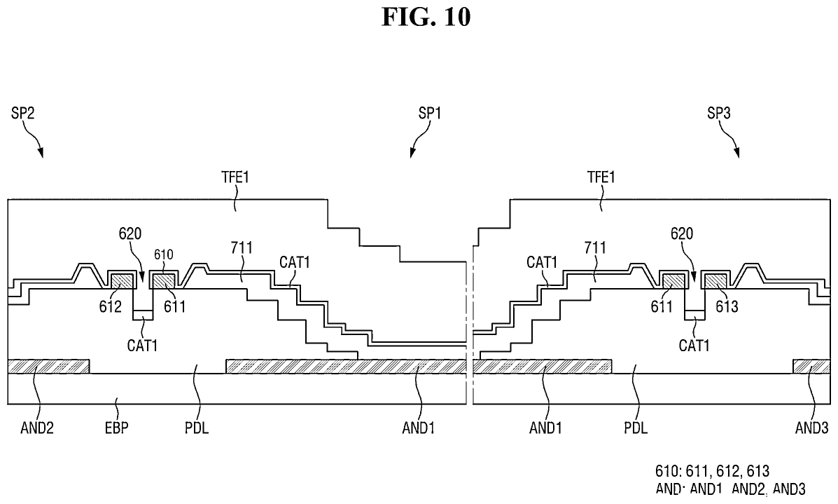

FIG. 10 is a schematic cross-sectional view illustrating a (1-5)^{th} operation of depositing a first encapsulation layer TFE1. Referring to FIG. 10, in the (1-5)^{th} operation, the first encapsulation layer TFE1 may be deposited on the entire surface of the substrate SSUB. The first encapsulation layer TFE1 may include a multilayer in which at least one encapsulating inorganic layer and at least one organic layer are stacked, like the encapsulation layer TFE described with reference to FIG. 5.

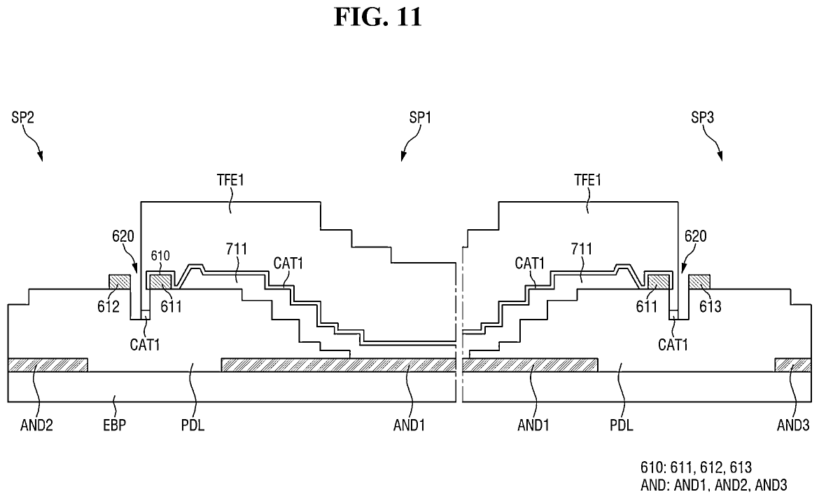

FIG. 11 is a schematic cross-sectional view illustrating a (1-6)^{th} operation of partially photo-patterning the first encapsulation layer TFE1, the first common electrode CAT1, and the first organic material 711. Referring to FIG. 11, in the (1-6)^{th} operation, a first photo-patterning process may be performed. For example, the first organic material 711, the first common electrode CAT1, and the first encapsulation layer TFE1 deposited in the second subpixel SP2 and the third subpixel SP3 may be removed using the first photo-patterning process. For example, the first organic material 711, the first common electrode CAT1, and the first encapsulation layer TFE1 deposited in a portion of the trench 620 surrounding the first subpixel SP1 may be left (or remained).

FIG. 12 is a schematic cross-sectional view illustrating a (1-7)^{th} operation of depositing and patterning a second organic material 712 and a third organic material 713 in a similar manner to the (1-2)^{th} through (1-6)^{th} operations. Referring to FIG. 12, the (1-7)^{th} operation may include depositing and patterning the second organic material 712 and depositing and patterning the third organic material 713.

For example, the second organic material 712 of the second subpixel SP2 may be deposited on the entire surface of the substrate SSUB. The second organic material 712 may include a second light emitting layer that emits light of the second color in a green wavelength band. The second organic material 712 may be commonly deposited not only in the second subpixel SP2 for displaying the second color, but also in the first subpixel SP1 for displaying the first color and the third subpixel SP3 for displaying the third color.

For example, a joule heating voltage may be applied to the heating wires 610, and the second organic material 712 disposed around the heating wires 610 may be removed using the heated heating wires 610. For example, the second organic material 712 disposed around the heating wires 610, on the heating wires 610, and in the trench 620 may be removed.

For example, a second common electrode CAT2 may be deposited on the entire surface of the substrate SSUB. The second common electrode CAT2 may be deposited on the second organic material 712, the pixel defining layer PDL disposed around the heating wires 610, the heating wires 610, and the trench 620.

For example, a second encapsulation layer TFE2 may be deposited on the entire surface of the substrate SSUB. The second encapsulation layer TFE2 may include a multilayer in which at least one encapsulating inorganic layer and at least one organic layer are stacked, like the encapsulation layer TFE described with reference to FIG. 5.

For example, a second photo-patterning process may be performed. For example, the second organic material 712, the second common electrode CAT2, and the second encapsulation layer TFE2 deposited in the first subpixel SP1 and the third subpixel SP3 may be removed using the second photo-patterning process. For example, the second organic material 712, the second common electrode CAT2, and the second encapsulation layer TFE2 deposited in a portion of the trench 620 surrounding the second subpixel SP2 may be left (or remained).

For example, the third organic material 713 of the third subpixel SP3 may be deposited on the entire surface of the substrate SSUB. The third organic material 713 may include a third light emitting layer that emits light of the third color in a blue wavelength band. The third organic material 713 may be commonly deposited not only in the third subpixel SP3 for displaying the third color, but also in the first subpixel SP1 for displaying the first color and the second subpixel SP2 for displaying the second color.

For example, a joule heating voltage may be applied to the heating wires 610, and the third organic material 713 disposed around the heating wires 610 may be removed using the heated heating wires 610. For example, the third organic material 713 disposed around the heating wires 610, on the heating wires 610, and in the trench 620 may be removed.

For example, a third common electrode CAT3 may be deposited on the entire surface of the substrate SSUB. The third common electrode may be deposited on the third organic material 713, the pixel defining layer PDL disposed around the heating wires 610, the heating wires 610, and the trench 620.

For example, a third encapsulation layer TFE3 may be deposited on the entire surface of the substrate SSUB. The third encapsulation layer TFE3 may include a multilayer in which at least one encapsulating inorganic layer and at least one organic layer are stacked, like the encapsulation layer TFE described with reference to FIG. 5. According to an embodiment, the stacked structure of the first encapsulation layer TFE1, the stacked structure of the second encapsulation layer TFE2, and the stacked structure of the third encapsulation layer TFE3 may all be the same.

For example, a third photo-patterning process may be performed. For example, the third organic material 713, the third common electrode CAT3, and the third encapsulation layer TFE3 deposited in the first subpixel SP1 and the second subpixel SP2 may be removed using the third photo-patterning process. For example, the third organic material 713, the third common electrode CAT3, and the third encapsulation layer TFE3 deposited in a portion of the trench 620 surrounding the third subpixel SP3 may be left (or remained).

According to an embodiment, the trench 620 between the first subpixel SP1 and the second subpixel SP2 may be divided into a first area 620_1 adjacent to the first subpixel SP1 and a second area 620_2 adjacent to the second subpixel SP2. The first common electrode CAT1 and the first encapsulation layer TFE1 covering the first common electrode CAT1 may be disposed in the first area 620_1. The second common electrode CAT2 and the second encapsulation layer TFE2 covering the second common electrode CAT2 may be disposed in the second area 620_2.

According to an embodiment, the trench 620 between the second subpixel SP2 and the third subpixel SP3 may be divided into a second area 620_2 adjacent to the second subpixel SP2 and a third area 620_3 adjacent to the third subpixel SP3. The second common electrode CAT2 and the second encapsulation layer TFE2 covering the second common electrode CAT2 may be disposed in the second area 620_2, and the third common electrode CAT3 and the third encapsulation layer TFE3 covering the third common electrode CAT3 may be disposed in the third area 620_3.

According to an embodiment, the trench 620 between the first subpixel SP1 and the third subpixel SP3 may be divided into a first area 6201 adjacent to the first subpixel SP1 and a third area 620_3 adjacent to the third subpixel SP3. The first common electrode CAT1 and the first encapsulation layer TFE1 covering the first common electrode CAT1 may be disposed in the first area 620_1. The third common electrode CAT3 and the third encapsulation layer TFE3 covering the third common electrode CAT3 may be disposed in the third area 620_3.

In a display device 10 according to an embodiment, each of the first encapsulation layer TFE1, the second encapsulation layer TFE2, and the third encapsulation layer TFE3 may contact (e.g., directly contact) the surface of the pixel defining layer PDL in the trench 620, thereby improving the encapsulation performance. For example, in the display panel 410, the encapsulation layer TFE may contact (e.g., directly contact) the surface of the pixel defining layer PDL in the trench 620, thereby reducing lateral damage (e.g., deterioration) to the first organic material 711, the second organic material 712, and the third organic material 713.

According to an embodiment, a trench-free area 2010 (in, e.g., FIG. 20) in which no trench 620 is formed is disposed outside each of the subpixels SP1 through SP3. The first common electrode CAT1, the second common electrode CAT2, and the third common electrode CAT3 may be electrically connected through the trench-free area 2010. Accordingly, the common electrodes CAT respectively provided in the subpixels SP1 through SP3 may be electrically connected without being disconnected from each other.

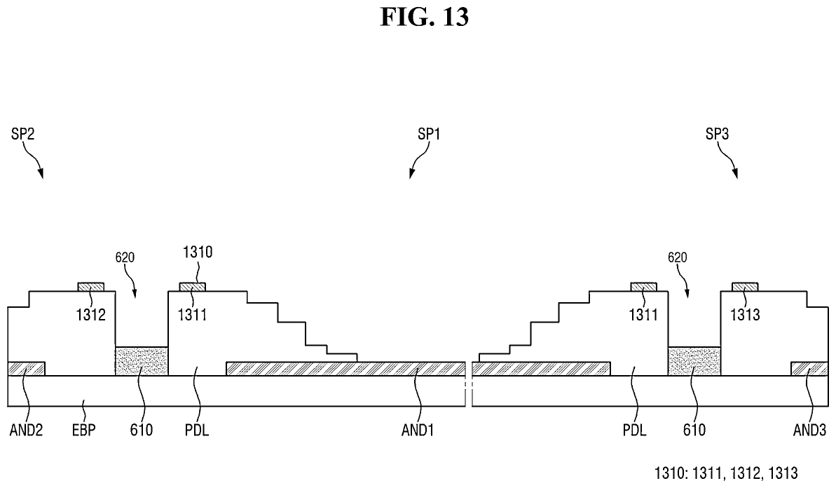

FIGS. 13 through 19 are schematic cross-sectional views illustrating a method of manufacturing a display panel 410 using a heating wire 610 disposed on a bottom surface of a trench 620. FIGS. 13 through 19 illustrate the display panel 410 of a display device 10, a semiconductor backplane SBP disposed on the substrate SSUB, and a light emitting element backplane EBP disposed on the semiconductor backplane SBP. A description of the unillustrated elements will be replaced with the description given with reference to FIG. 5 for descriptive convenience.

The embodiment of FIGS. 13 through 19 is different from the embodiment of FIGS. 6 through 12 in that the heating wire 610 is disposed on the bottom surface of the trench 620.

The method of manufacturing the display panel 410 in which an organic material is deposited and patterned for each subpixel by using the heating wire 610 disposed on the bottom surface of the trench 620 will now be described with reference to FIGS. 13 through 19.

FIG. 13 is a schematic cross-sectional view illustrating a (2-1)^{th} operation of forming a heating wire 610 according to an embodiment on a bottom surface of a trench 620.

Referring to FIG. 13, in the (2-1)^{th} operation, the substrate SSUB of the display panel 410 may be prepared. The substrate SSUB may be a substrate (e.g., semiconductor substrate) SSUB.

For example, the semiconductor backplane SBP and the light emitting element backplane EBP described with reference to FIG. 5 may be sequentially formed on the substrate SSUB.

For example, a pixel electrode AND (e.g., AND1, AND2, and AND3) of each of subpixels SP1 through SP3 may be deposited.

For example, a pixel defining layer PDL may be deposited on the pixel electrodes AND to define the subpixels SP1 through SP3. The pixel defining layer PDL may be patterned to expose a portion of the pixel electrode AND of each of the subpixels SP1 through SP3. For example, the pixel electrode AND of each of the subpixels SP1 through SP3 may be exposed through an opening of the pixel defining layer PDL during a process.

For example, a portion of the pixel defining layer PDL between neighboring subpixels (or adjacent subpixels) SP1 through SP3 may be etched to form the trench 620 surrounding at least a portion of each of the subpixels SP1 through SP3. For example, the trench 620 may not completely surround each of the subpixels SP1 through SP3 and may not be formed in some areas. An area in which the trench 620 is not formed may be referred to as a “trench-free area 2010.” The trench-free area 2010 may be an area for preventing disconnection of common electrodes CAT from each other.

For example, the heating wire 610 may be formed on the bottom surface of the trench 620. The heating wire 610 may surround at least a portion of each of the subpixels SP1 through SP3. For example, auxiliary common electrodes 1310 may be formed apart from each other with the trench 620 interposed between the auxiliary common electrodes 1310. For example, a pair of auxiliary common electrodes 1310 may be disposed between neighboring subpixels (or adjacent subpixels) SP1 through SP3 and may be spaced apart from each other with the trench 620 interposed between the pair of auxiliary common electrodes 1310. The heating wire 610 may receive a joule heating voltage from the outside and may be heated to a specified temperature (e.g., about 400° C.) or higher based on the received joule heating voltage. The heating wire 610 may function to remove an organic material deposited around it, as will be described later.

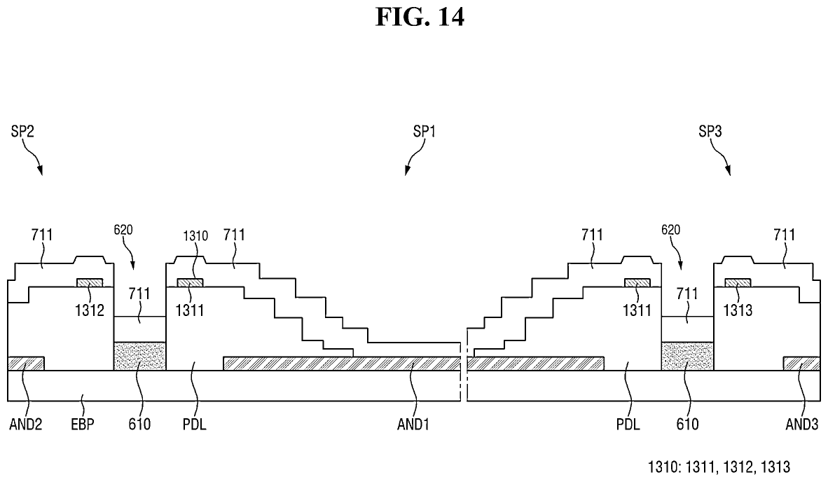

FIG. 14 is a schematic cross-sectional view illustrating a (2-2)^{th} operation of depositing a first organic material 711. Referring to FIG. 14, in the (2-2)^{th} operation, the first organic material 711 of a first subpixel SP1 may be deposited on the entire surface of the substrate SSUB. The first organic material 711 may include a first light emitting layer that emits light of a first color in a red wavelength band. The first organic material 711 may be commonly deposited not only in the first subpixel SP1 for displaying the first color, but also in a second subpixel SP2 for displaying a second color and a third subpixel SP3 for displaying a third color.

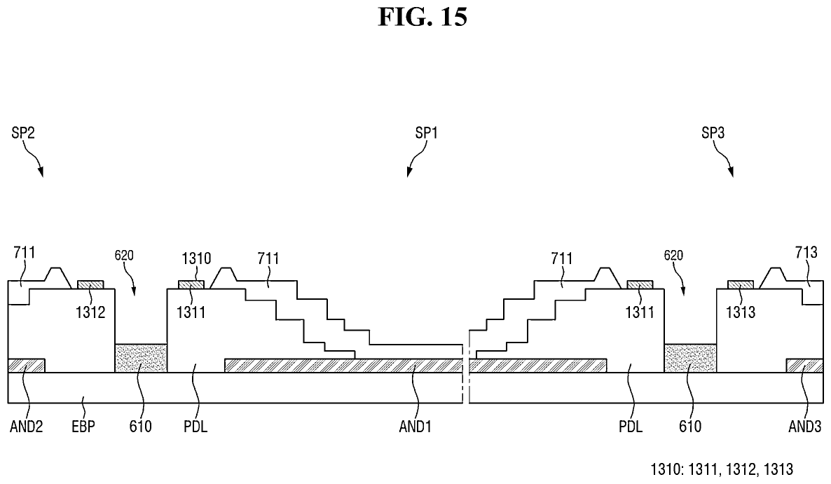

FIG. 15 is a schematic cross-sectional view illustrating a (2-3)^{th} operation of removing a portion of the first organic material 711 by using the heating wire 610. Referring to FIG. 15, in the (2-3)^{th} operation, a joule heating voltage may be applied to the heating wire 610, and the first organic material 711 disposed around the heating wire 610 may be removed using the heated heating wire 610. For example, the first organic material 711, which is disposed around the heating wire 610, on the heating wire 610, and in the trench 620, may be removed.

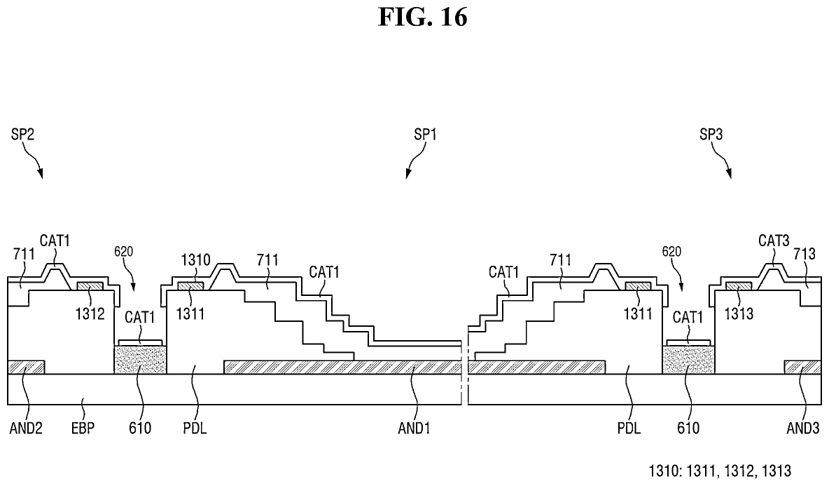

FIG. 16 is a schematic cross-sectional view illustrating a (2-4)^{th} operation of depositing a first common electrode CAT1. Referring to FIG. 16, in the (2-4)^{th} operation, the first common electrode CAT1 may be deposited on the entire surface of the substrate SSUB. The first common electrode CAT1 may be deposited on the first organic material 711, the pixel defining layer PDL disposed around the heating wire 610, the auxiliary common electrodes 1310, and the trench 620.

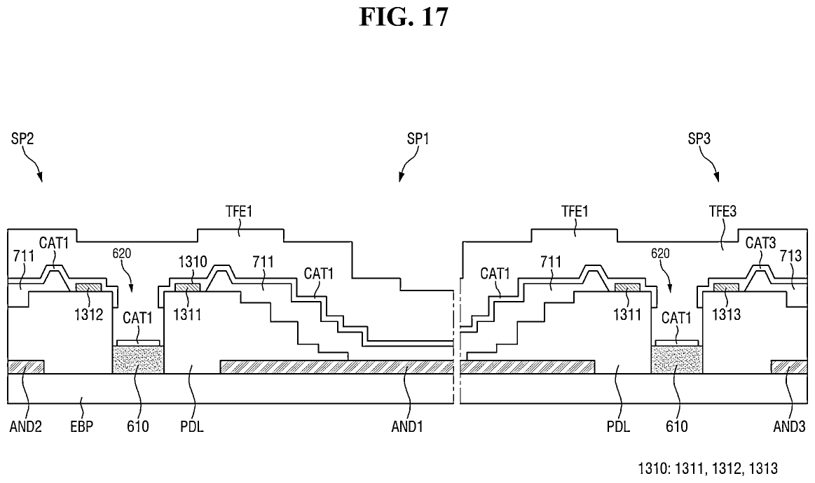

FIG. 17 is a schematic cross-sectional view illustrating a (2-5)^{th} operation of depositing a first encapsulation layer TFE1. Referring to FIG. 17, in the (2-5)^{th} operation, the first encapsulation layer TFE1 may be deposited on the entire surface of the substrate SSUB. The first encapsulation layer TFE1 may include a multilayer in which at least one encapsulating inorganic layer and at least one organic layer are stacked, like the encapsulation layer TFE described with reference to FIG. 5.

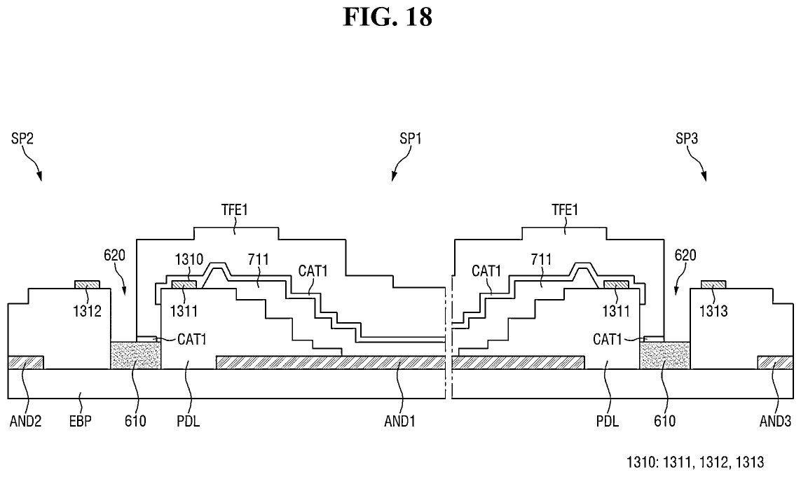

FIG. 18 is a schematic cross-sectional view illustrating a (2-6)^{th} operation of partially photo-patterning the first encapsulation layer TFE1, the first common electrode CAT1, and the first organic material 711. Referring to FIG. 18, in the (2-6)^{th} operation, a first photo-patterning process may be performed. For example, the first organic material 711, the first common electrode CAT1, and the first encapsulation layer TFE1 deposited in the second subpixel SP2 and the third subpixel SP3 may be removed using the first photo-patterning process. For example, the first organic material 711, the first common electrode CAT1, and the first encapsulation layer TFE1 deposited in a portion of the trench 620 surrounding the first subpixel SP1 may be left (or remained).

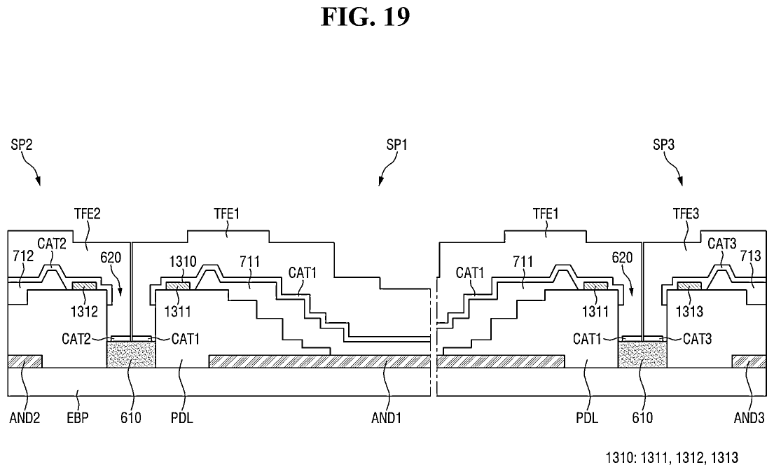

FIG. 19 is a schematic cross-sectional view illustrating a (2-7)^{th} operation of depositing and patterning a second organic material 712 and a third organic material 713 in a similar manner to the (2-2)^{th} through (2-6)^{th} operations. Referring to FIG. 19, the (2-7)^{th} operation may include depositing and patterning the second organic material 712 and depositing and patterning the third organic material 713.

For example, the second organic material 712 of the second subpixel SP2 may be deposited on the entire surface of the substrate SSUB. The second organic material 712 may include a second light emitting layer that emits light of the second color in a green wavelength band. The second organic material 712 may be commonly deposited not only in the second subpixel SP2 for displaying the second color, but also in the first subpixel SP1 for displaying the first color and the third subpixel SP3 for displaying the third color.

a joule heating voltage may be applied to the heating wire 610, and the second organic material 712 disposed around the heating wire 610 may be removed using the heated heating wire 610. For example, the second organic material 712 disposed around the heating wire 610, on the heating wire 610, and in the trench 620 may be removed.

For example, a second common electrode CAT2 may be deposited on the entire surface of the substrate SSUB. The second common electrode CAT2 may be deposited on the second organic material 712, the pixel defining layer PDL disposed around the heating wire 610, the auxiliary common electrodes 1310, and the trench 620.

For example, a second encapsulation layer TFE2 may be deposited on the entire surface of the substrate SSUB. The second encapsulation layer TFE2 may include a multilayer in which at least one encapsulating inorganic layer and at least one organic layer are stacked, like the encapsulation layer TFE described with reference to FIG. 5.

For example, a second photo-patterning process may be performed. For example, the second organic material 712, the second common electrode CAT2, and the second encapsulation layer TFE2 deposited in the first subpixel SP1 and the third subpixel SP3 may be removed using the second photo-patterning process. For example, the second organic material 712, the second common electrode CAT2, and the second encapsulation layer TFE2 deposited in a portion of the trench 620 surrounding the second subpixel SP2 may be left (or remained).

For example, the third organic material 713 of the third subpixel SP3 may be deposited on the entire surface of the substrate SSUB. The third organic material 713 may include a third light emitting layer that emits light of the third color in a blue wavelength band. The third organic material 713 may be commonly deposited not only in the third subpixel SP3 for displaying the third color, but also in the first subpixel SP1 for displaying the first color and the second subpixel SP2 for displaying the second color.

For example, a joule heating voltage may be applied to the heating wire 610, and the third organic material 713 disposed around the heating wire 610 may be removed using the heated heating wire 610. For example, the third organic material 713 disposed around the heating wire 610, on the heating wire 610, and in the trench 620 may be removed.

For example, a third common electrode CAT3 may be deposited on the entire surface of the substrate SSUB. The third common electrode CAT3 may be deposited on the third organic material 713, the pixel defining layer PDL disposed around the heating wire 610, the auxiliary common electrodes 1310, and the trench 620.

For example, a third encapsulation layer TFE3 may be deposited on the entire surface of the substrate SSUB. The third encapsulation layer TFE3 may include a multilayer in which at least one encapsulating inorganic layer and at least one organic layer are stacked, like the encapsulation layer TFE described with reference to FIG. 5.

For example, a third photo-patterning process may be performed. For example, the third organic material 713, the third common electrode CAT3, and the third encapsulation layer TFE3 deposited in the first subpixel SP1 and the second subpixel SP2 may be removed using the third photo-patterning process. For example, the third organic material 713, the third common electrode CAT3, and the third encapsulation layer TFE3 deposited in a portion of the trench 620 surrounding the third subpixel SP3 may be left (or remained).

FIG. 20 is a layout view illustrating a part of the display panel 410 to explain the auxiliary common electrodes 1310 according to an embodiment. For example, FIG. 20 illustrates the heating wire 610 and the auxiliary common electrodes 1310 illustrated in FIGS. 13 through 19.

Referring to FIG. 20, a trench-free area 2010 in which no trench 620 is formed may be disposed outside each of the subpixels SP1 through SP3. The first auxiliary common electrode 1311, the second auxiliary common electrode 1312, and the third auxiliary common electrode 1313 may be electrically connected through the trench-free area 2010. Accordingly, the common electrodes CAT respectively provided in the subpixels SP1 through SP3 may be electrically connected without being disconnected from each other.

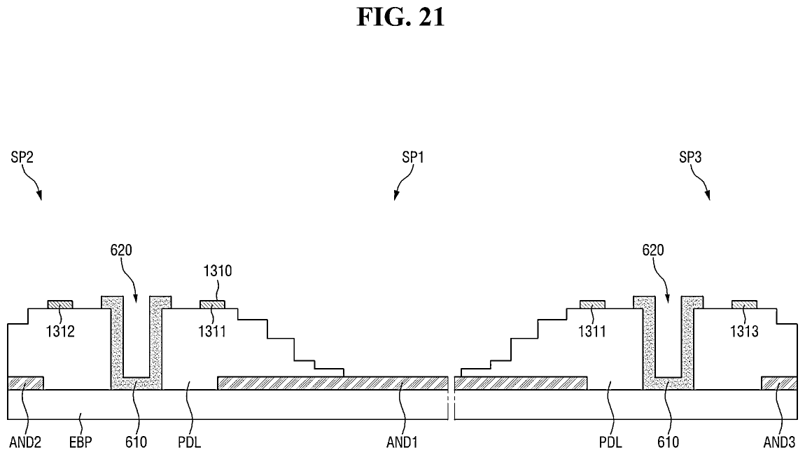

FIGS. 21 through 27 are schematic cross-sectional views illustrating a method of manufacturing a display panel 410 using a heating wire 610 extending from a bottom surface of a trench 620 onto a pixel defining layer PDL. FIGS. 21 through 27 illustrate the display panel 410 of a display device 10, a semiconductor backplane SBP disposed on the substrate SSUB, and a light emitting element backplane EBP disposed on the semiconductor backplane SBP. A description of the unillustrated elements will be replaced with the description given with reference to FIG. 5 for descriptive convenience.

The embodiment of FIGS. 21 through 27 is different from the embodiment of FIGS. 13 through 19 in that the heating wire 610 extends from the bottom surface of the trench 620 onto the pixel defining layer PDL.

The method of manufacturing the display panel 410 in which an organic material is deposited and patterned for each subpixel by using the heating wire 610 extending from the bottom surface of the trench 620 onto the pixel defining layer PDL will now be described with reference to FIGS. 21 through 27.

FIG. 21 is a schematic cross-sectional view illustrating a (3-1)^{th} operation of forming a heating wire 610 according to an embodiment on a bottom surface of a trench 620 and a pixel defining layer PDL.

Referring to FIG. 21, in the (3-1)^{th} operation, the substrate SSUB of the display panel 410 may be prepared. The substrate SSUB may be a semiconductor substrate.

For example, the semiconductor backplane SBP and the light emitting element backplane EBP described with reference to FIG. 5 may be sequentially formed on the substrate SSUB.

For example, a pixel electrode AND (e.g., AND1, AND2, and AND3) of each of subpixels SP1 through SP3 may be deposited.

For example, the pixel defining layer PDL may be deposited on the pixel electrodes AND to define the subpixels SP1 through SP3. The pixel defining layer PDL may be patterned to expose a portion of the pixel electrode AND of each of the subpixels SP1 through SP3. For example, the pixel electrode AND of each of the subpixels SP1 through SP3 may be exposed through an opening of the pixel defining layer PDL during a process.

For example, a portion of the pixel defining layer PDL between neighboring subpixels (or adjacent subpixels) SP1 through SP3 may be etched to form the trench 620 surrounding at least a portion of each of the subpixels SP1 through SP3. For example, the trench 620 may not completely surround each of the subpixels SP1 through SP3 and may not be formed in some areas. An area in which the trench 620 is not formed may be referred to as a “trench-free area 2010.” The trench-free area 2010 may be an area for preventing disconnection of common electrodes CAT from each other.

For example, the heating wire 610 may be formed on the bottom surface of the trench 620. The heating wire 610 may surround at least a portion of each of the subpixels SP1 through SP3. For example, auxiliary common electrodes 1310 may be formed apart from each other with the trench 620 interposed between the auxiliary common electrodes 1310. For example, a pair of auxiliary common electrodes 1310 may be disposed between neighboring subpixels (or adjacent subpixels) SP1 through SP3 and may be spaced apart from each other with the trench 620 interposed between the pair of auxiliary common electrodes 1310. The heating wire 610 may receive a joule heating voltage from the outside and may be heated to a specified temperature (e.g., about 400° C.) or higher based on the received joule heating voltage. The heating wire 610 may function to remove an organic material deposited around it, as will be described later.

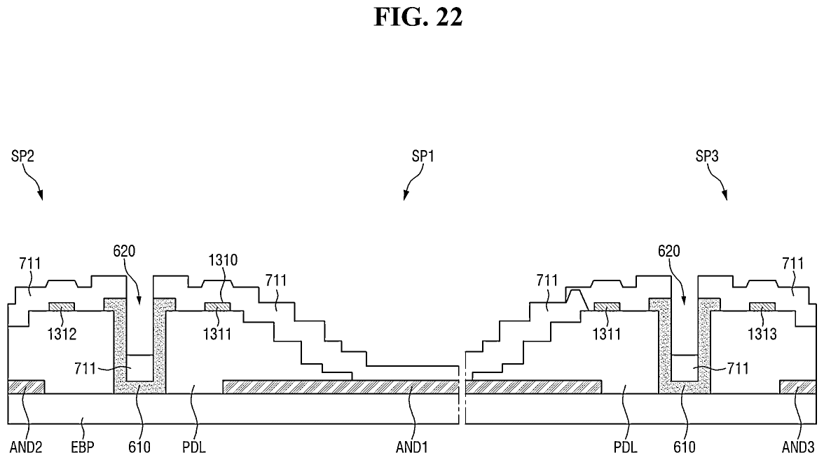

FIG. 22 is a schematic cross-sectional view illustrating a (3-2)^{th} operation of depositing a first organic material 711. Referring to FIG. 22, in the (3-2)^{th} operation, the first organic material 711 of a first subpixel SP1 may be deposited on the entire surface of the substrate SSUB. The first organic material 711 may include a first light emitting layer that emits light of a first color in a red wavelength band. The first organic material 711 may be commonly deposited not only in the first subpixel SP1 for displaying the first color, but also in a second subpixel SP2 for displaying a second color and a third subpixel SP3 for displaying a third color.

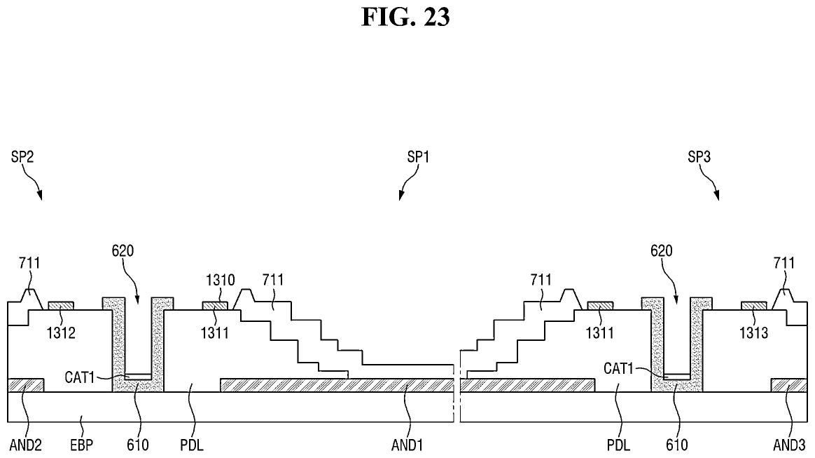

FIG. 23 is a schematic cross-sectional view illustrating a (3-3)^{th} operation of removing a portion of the first organic material 711 by using the heating wire 610. Referring to FIG. 23, in the (3-3)^{th} operation, a joule heating voltage may be applied to the heating wire 610, and the first organic material 711 disposed around the heating wire 610 may be removed using the heated heating wire 610. For example, the first organic material 711 disposed around the heating wire 610, on the heating wire 610, and in the trench 620 may be removed.

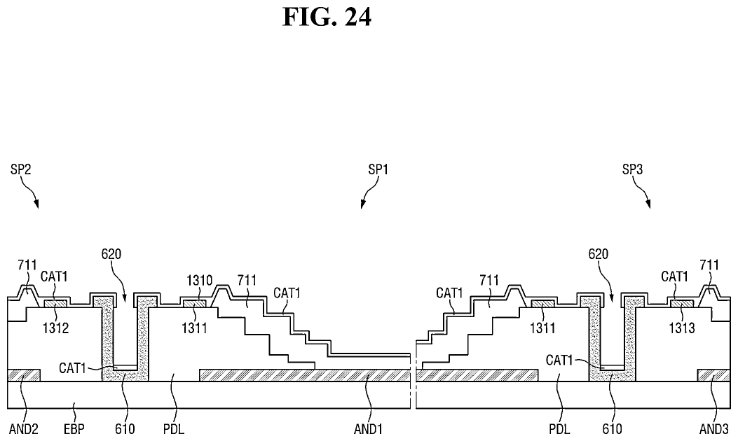

FIG. 24 is a schematic cross-sectional view illustrating a (3-4)^{th} operation of depositing a first common electrode CAT1. Referring to FIG. 24, in the (3-4)^{th} operation, the first common electrode CAT1 may be deposited on the entire surface of the substrate SSUB. The first common electrode CAT1 may be deposited on the first organic material 711, the pixel defining layer PDL disposed around the heating wire 610, the auxiliary common electrodes 1310, and the trench 620.

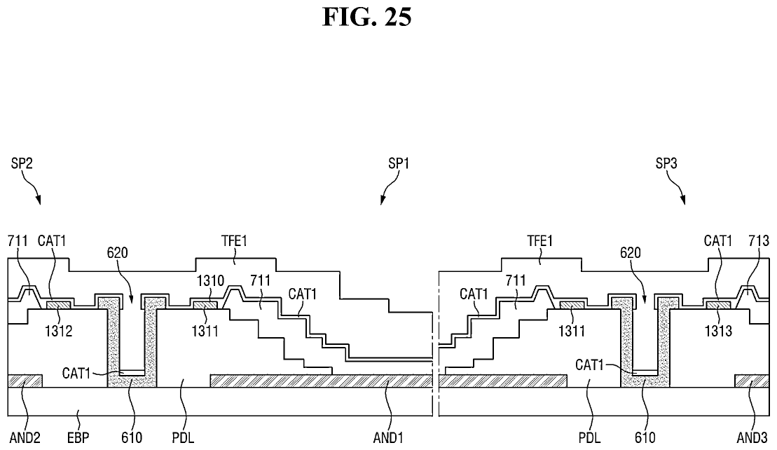

FIG. 25 is a schematic cross-sectional view illustrating a (3-5)^{th} operation of depositing a first encapsulation layer TFE1. Referring to FIG. 25, in the (3-5)^{th} operation, the first encapsulation layer TFE1 may be deposited on the entire surface of the substrate SSUB. The first encapsulation layer TFE1 may include a multilayer in which at least one encapsulating inorganic layer and at least one organic layer are stacked, like the encapsulation layer TFE described with reference to FIG. 5.

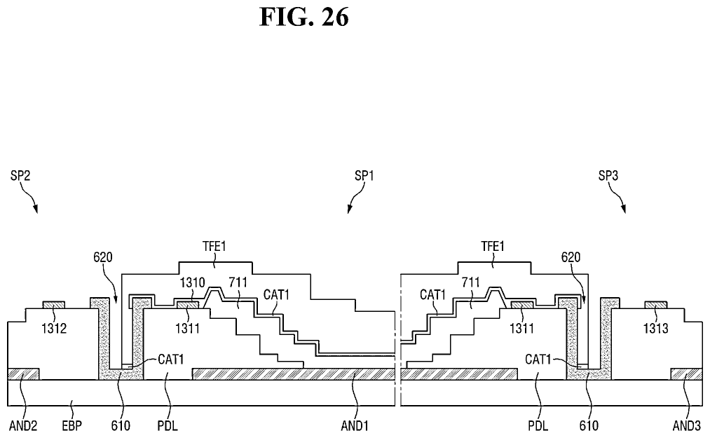

FIG. 26 is a schematic cross-sectional view illustrating a (3-6)^{th} operation of partially photo-patterning the first encapsulation layer TFE1, the first common electrode CAT1, and the first organic material 711. Referring to FIG. 26, in the (3-6)^{th} operation, a first photo-patterning process may be performed. For example, the first organic material 711, the first common electrode CAT1, and the first encapsulation layer TFE1 deposited in the second subpixel SP2 and the third subpixel SP3 may be removed using the first photo-patterning process. For example, the first organic material 711, the first common electrode CAT1, and the first encapsulation layer TFE1 deposited in a portion of the trench 620 surrounding the first subpixel SP1 may be left (or remained).

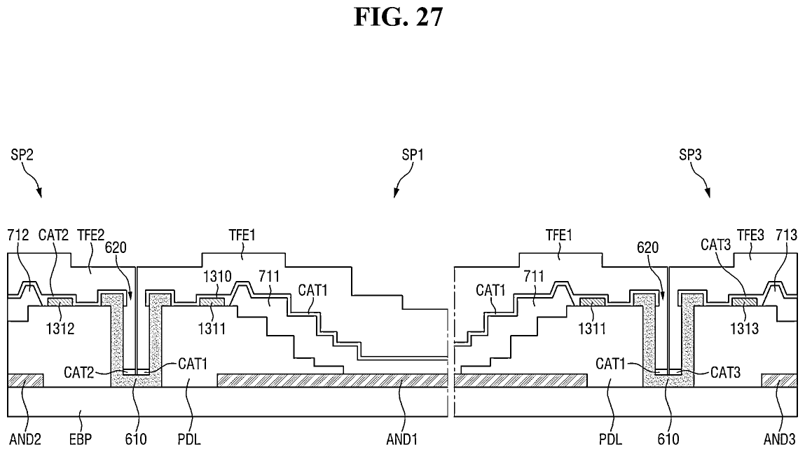

FIG. 27 is a schematic cross-sectional view illustrating a (3-7)^{th} operation of depositing and patterning a second organic material 712 and a third organic material 713 in a similar manner to the (3-2)^{th} through (3-6)^{th} operations. Referring to FIG. 27, the (3-7)^{th} operation may include depositing and patterning the second organic material 712 and depositing and patterning the third organic material 713.

For example, the second organic material 712 of the second subpixel SP2 may be deposited on the entire surface of the substrate SSUB. The second organic material 712 may include a second light emitting layer that emits light of the second color in a green wavelength band. The second organic material 712 may be commonly deposited not only in the second subpixel SP2 for displaying the second color, but also in the first subpixel SP1 for displaying the first color and the third subpixel SP3 for displaying the third color.

a joule heating voltage may be applied to the heating wire 610, and the second organic material 712 disposed around the heating wire 610 may be removed using the heated heating wire 610. For example, the second organic material 712 disposed around the heating wire 610, on the heating wire 610, and in the trench 620 may be removed.

For example, a second common electrode CAT2 may be deposited on the entire surface of the substrate SSUB. The second common electrode CAT2 may be deposited on the second organic material 712, the pixel defining layer PDL disposed around the heating wire 610, the auxiliary common electrodes 1310, and the trench 620.

For example, a second encapsulation layer TFE2 may be deposited on the entire surface of the substrate SSUB. The second encapsulation layer TFE2 may include a multilayer in which at least one encapsulating inorganic layer and at least one organic layer are stacked, like the encapsulation layer TFE described with reference to FIG. 5.

For example, a second photo-patterning process may be performed. For example, the second organic material 712, the second common electrode CAT2, and the second encapsulation layer TFE2 deposited in the first subpixel SP1 and the third subpixel SP3 may be removed using the second photo-patterning process. For example, the second organic material 712, the second common electrode CAT2, and the second encapsulation layer TFE2 deposited in a portion of the trench 620 surrounding the second subpixel SP2 may be left (or remained).

For example, the third organic material 713 of the third subpixel SP3 may be deposited on the entire surface of the substrate SSUB. The third organic material 713 may include a third light emitting layer that emits light of the third color in a blue wavelength band. The third organic material 713 may be commonly deposited not only in the third subpixel SP3 for displaying the third color, but also in the first subpixel SP1 for displaying the first color and the second subpixel SP2 for displaying the second color.

For example, a joule heating voltage may be applied to the heating wire 610, and the third organic material 713 disposed around the heating wire 610 may be removed using the heated heating wire 610. For example, the third organic material 713 disposed around the heating wire 610, on the heating wire 610, and in the trench 620 may be removed.

For example, a third common electrode CAT3 may be deposited on the entire surface of the substrate SSUB. The third common electrode CAT3 may be deposited on the third organic material 713, the pixel defining layer PDL disposed around the heating wire 610, the auxiliary common electrodes 1310, and the trench 620.

For example, a third encapsulation layer TFE3 may be deposited on the entire surface of the substrate SSUB. The third encapsulation layer TFE3 may include a multilayer in which at least one encapsulating inorganic layer and at least one organic layer are stacked, like the encapsulation layer TFE described with reference to FIG. 5.

For example, a third photo-patterning process may be performed. For example, the third organic material 713, the third common electrode CAT3, and the third encapsulation layer TFE3 deposited in the first subpixel SP1 and the second subpixel SP2 may be removed using the third photo-patterning process. For example, the third organic material 713, the third common electrode CAT3, and the third encapsulation layer TFE3 deposited in a portion of the trench 620 surrounding the third subpixel SP3 may be left (or remained).

In the embodiment of FIGS. 21 through 27, the auxiliary common electrodes 1310 may also be omitted. For example, the heating wire 610 extending onto the pixel defining layer PDL may electrically connect the first common electrode CAT1, the second common electrode CAT2, and the third common electrode CAT3 through a trench-free area 2010.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A method of manufacturing a display device, the method comprising:
forming a semiconductor backplane and a light emitting element backplane on a substrate; and
forming a light emitting element layer and an encapsulation layer on the light emitting element backplane,
wherein the forming of the light emitting element layer and the encapsulation layer comprises:
depositing a pixel electrode of each of a plurality of subpixels;
depositing a pixel defining layer on the pixel electrodes to define the subpixels;
etching a portion of the pixel defining layer between adjacent subpixels to form a trench surrounding at least a portion of each of the subpixels;
forming heating wires on the pixel defining layer such that the heating wires are spaced apart from each other with the trench interposed therebetween;
depositing a first organic material of a first subpixel on an entire surface of the substrate;
removing a portion of the first organic material deposited around the heating wires and the trench by heating the heating wires;
depositing a first common electrode on the entire surface of the substrate;
depositing a first encapsulation layer on the entire surface of the substrate;
removing the first organic material, the first common electrode, and the first encapsulation layer deposited in a second subpixel and a third subpixel by using a first photo-patterning process and remaining the first organic material, the first common electrode, and the first encapsulation layer deposited in a portion of the trench surrounding the first subpixel;
depositing a second organic material of the second subpixel on the entire surface of the substrate;
removing a portion of the second organic material deposited around the heating wires and the trench by heating the heating wires;
depositing a second common electrode on the entire surface of the substrate;
depositing a second encapsulation layer on the entire surface of the substrate;
removing the second organic material, the second common electrode, and the second encapsulation layer deposited in the first subpixel and the third subpixel by using a second photo-patterning process and remaining the second organic material, the second common electrode, and the second encapsulation layer deposited in a portion of the trench surrounding the second subpixel;
depositing a third organic material of the third subpixel on the entire surface of the substrate;
removing a portion of the third organic material deposited around the heating wires and the trench by heating the heating wires;
depositing a third common electrode on the entire surface of the substrate;
depositing a third encapsulation layer on the entire surface of the substrate;
removing the third organic material, the third common electrode, and the third encapsulation layer deposited in the first subpixel and the second subpixel by using a third photo-patterning process and remaining the third organic material, the third common electrode, and the third encapsulation layer deposited in a portion of the trench surrounding the third subpixel.

2. The method of claim 1, wherein
a trench-free area, in which the trench is not formed, is disposed outside each of the subpixels, and
the first common electrode, the second common electrode and the third common electrode are electrically connected through the trench-free area.

3. The method of claim 1, wherein
the trench between the first subpixel and the second subpixel is divided into a first area adjacent to the first subpixel and a second area adjacent to the second subpixel,
the first common electrode and the first encapsulation layer covering the first common electrode are disposed in the first area, and
the second common electrode and the second encapsulation layer covering the second common electrode are disposed in the second area.

4. The method of claim 1, wherein
the trench between the second subpixel and the third subpixel is divided into a second area adjacent to the second subpixel and a third area adjacent to the third subpixel,
the second common electrode and the second encapsulation layer covering the second common electrode are disposed in the second area, and
the third common electrode and the third encapsulation layer covering the third common electrode are disposed in the third area.

5. The method of claim 1, wherein
the trench between the first subpixel and the third subpixel is divided into a first area adjacent to the first subpixel and a third area adjacent to the third subpixel,
the first common electrode and the first encapsulation layer covering the first common electrode are disposed in the first area, and
the third common electrode and the third encapsulation layer covering the third common electrode are disposed in the third area.

6. The method of claim 1, wherein the first encapsulation layer, the second encapsulation layer, and the third encapsulation layer have a same stacked structure.

7. The method of claim 1, wherein
the first organic material comprises a first light emitting layer that emits light of a first color having a red wavelength band,
the second organic material comprises a second light emitting layer that emits light of a second color having a green wavelength band, and
the third organic material comprises a third light emitting layer that emits light of a third color having a blue wavelength band.

8. A display device comprising:
a pixel defining layer defining a plurality of subpixels;
a pixel electrode of each subpixel disposed in an opening of the pixel defining layer;
a trench formed by etching a portion of the pixel defining layer and surrounding at least a portion of each of the subpixels;
heating wires disposed on the pixel defining layer and spaced apart from each other with the trench disposed between the heating wires;
a first organic material covering a first pixel electrode of a first subpixel and a portion of the pixel defining layer surrounding the first pixel electrode;
a first common electrode covering the first organic material and a first heating wire around the first subpixel;
a first encapsulation layer covering the first common electrode and a portion of the trench around the first subpixel;
a second organic material covering a second pixel electrode of a second subpixel and a portion of the pixel defining layer surrounding the second pixel electrode;
a second common electrode covering the second organic material and a second heating wire around the second subpixel;
a second encapsulation layer covering the second common electrode and a portion of the trench around the second subpixel;
a third organic material covering a third pixel electrode of a third subpixel and a portion of the pixel defining layer surrounding the third pixel electrode;
a third common electrode covering the third organic material and a third heating wire around the third subpixel; and
a third encapsulation layer covering the third common electrode and a portion of the trench around the third subpixel.

9. The display device of claim 8, wherein
a trench-free area, in which the trench is not formed, is disposed outside each of the subpixels, and
the first common electrode, the second common electrode, and the third common electrode are electrically connected through the trench-free area.

10. The display device of claim 8, wherein
the trench between the first subpixel and the second subpixel is divided into a first area adjacent to the first subpixel and a second area adjacent to the second subpixel,
the first common electrode and the first encapsulation layer covering the first common electrode are disposed in the first area, and
the second common electrode and the second encapsulation layer covering the second common electrode are disposed in the second area.

11. The display device of claim 8, wherein
the trench between the second subpixel and the third subpixel is divided into a second area adjacent to the second subpixel and a third area adjacent to the third subpixel,
the second common electrode and the second encapsulation layer covering the second common electrode are disposed in the second area, and
the third common electrode and the third encapsulation layer covering the third common electrode are disposed in the third area.

12. The display device of claim 8, wherein
the trench between the first subpixel and the third subpixel is divided into a first area adjacent to the first subpixel and a third area adjacent to the third subpixel,
the first common electrode and the first encapsulation layer covering the first common electrode are disposed in the first area, and
the third common electrode and the third encapsulation layer covering the third common electrode are disposed in the third area.

13. The display device of claim 8, wherein the first encapsulation layer, the second encapsulation layer, and the third encapsulation layer have a same stacked structure.

14. The display device of claim 8, wherein
the first organic material comprises a first light emitting layer that emits light of a first color having a red wavelength band,
the second organic material comprises a second light emitting layer that emits light of a second color having a green wavelength band, and
the third organic material comprises a third light emitting layer that emits light of a third color having a blue wavelength band.

15. The display device of claim 8, further comprising:
a display panel in which a light emitting element layer is disposed on a semiconductor backplane.

16. A display device comprising:
a pixel defining layer defining a plurality of subpixels;
a pixel electrode of each subpixel disposed in an opening of the pixel defining layer;
a trench formed by etching a portion of the pixel defining layer and surrounding at least a portion of each of the subpixels;
a heating wire disposed on a bottom surface of the trench;
auxiliary common electrodes disposed on the pixel defining layer and spaced apart from each other with the trench disposed between the auxiliary common electrodes;
a first organic material covering a first pixel electrode of a first subpixel and a portion of the pixel defining layer surrounding the first pixel electrode;
a first common electrode covering the first organic material and a first auxiliary common electrode adjacent to the first pixel electrode;
a first encapsulation layer covering the first common electrode and a portion of the trench around the first subpixel;
a second organic material covering a second pixel electrode of a second subpixel and a portion of the pixel defining layer surrounding the second pixel electrode;
a second common electrode covering the second organic material and a second auxiliary common electrode adjacent to the second pixel electrode;
a second encapsulation layer covering the second common electrode and a portion of the trench around the second subpixel;
a third organic material covering a third pixel electrode of a third subpixel and a portion of the pixel defining layer surrounding the third pixel electrode;
a third common electrode covering the third organic material and a third auxiliary common electrode adjacent to the third pixel electrode; and
a third encapsulation layer covering the third common electrode and a portion of the trench around the third subpixel.

17. The display device of claim 16, wherein
a trench-free area, in which the trench is not formed, is disposed outside each of the subpixels, and the first auxiliary common electrode,
the second auxiliary common electrode and the third auxiliary common electrode are electrically connected through the trench-free area.

18. The display device of claim 16, wherein
the trench between the first subpixel and the second subpixel is divided into a first area adjacent to the first subpixel and a second area adjacent to the second subpixel,
the first common electrode and the first encapsulation layer covering the first common electrode are disposed in the first area, and
the second common electrode and the second encapsulation layer covering the second common electrode are disposed in the second area.

19. The display device of claim 16, wherein
the trench between the second subpixel and the third subpixel is divided into a second area adjacent to the second subpixel and a third area adjacent to the third subpixel,
the second common electrode and the second encapsulation layer covering the second common electrode are disposed in the second area, and
the third common electrode and the third encapsulation layer covering the third common electrode are disposed in the third area.

20. The display device of claim 16, wherein
the trench between the first subpixel and the third subpixel is divided into a first area adjacent to the first subpixel and a third area adjacent to the third subpixel,
the first common electrode and the first encapsulation layer covering the first common electrode are disposed in the first area, and
the third common electrode and the third encapsulation layer covering the third common electrode are disposed in the third area.
